(19) United States
(12) Patent Application Publication
(10) Pub. No.: US 2012/0050844 A1
(43) Pub. Date: Mar. 1, 2012

(54) OPTICAL SIGNAL TRANSMISSION DEVICE, OPTICAL AMPLIFICATION DEVICE, OPTICAL ATTENUATION DEVICE AND OPTICAL SIGNAL TRANSMISSION METHOD

(75) Inventors: Masato Nishihara, Kawasaki (JP); Toshiki Tanaka, Kawasaki (JP)

(73) Assignee: FUJITSU LIMITED, Kawasaki-shi (JP)

(21) Appl. No.: 13/033,786

(22) Filed: Feb. 24, 2011

(30) Foreign Application Priority Data
Mar. 8, 2010 (JP) 2010-050949

(51) Int. Cl. H01S 5/00; H01S 3/13; H01S 3/067

(52) U.S. Cl. 359/337.13; 359/344; 359/341.3

(57) ABSTRACT

A generation unit generates a polarization multiplexing signal in which two optical signals, each polarization of which is orthogonal to each other, are combined. A detector detects the powers of the two optical signals contained in the polarization multiplexing signal generated by the generation unit. An amplifier amplifies, according to each polarization of the two optical signals contained in the polarization multiplexing signal generated by the generation unit, the powers of the two optical signals. An controller controls a gain of the amplifier with respect to each polarization of the two optical signals so as to reduce difference in the powers of the two optical signals detected by the detector.

### CROSS-REFERENCE TO RELATED APPLICATION

This application is based upon and claims the benefit of priority of the prior Japanese Patent Application No. 2010-050949, filed on Mar. 8, 2010, the entire contents of which are incorporated herein by reference.

### FIELD

The embodiments discussed herein are directed to a optical signal transmission device, a optical amplification device, a optical attenuation device, and a optical signal transmission method.

### BACKGROUND

Various transmission methods for efficiently transmitting information are recently being reviewed to realize a high-speed optical transmission system exceeding 40 Gbit/s. The polarization multiplexing method is particularly given attention for such transmission method. The polarization multiplexing method is a method of transmitting two independent data signals at once using a polarization multiplexing signal in which two optical signals, each polarization of which is orthogonal to each other, are combined.

The conventional optical signal transmission device employing the polarization multiplexing method will now be described using FIG. 31. FIG. 31 is a view illustrating a configuration of a conventional optical signal transmission device that uses the polarization multiplexing method. As illustrated in the figure, a conventional optical signal transmission device 10 includes a generation unit 11 and an amplifier 12. The generation unit 11 generates a polarization multiplexing signal in which two optical signals, each polarization of which is orthogonal to each other, are combined. Specifically, the generation unit 11 includes a light source 13, a divider 14, a first modulator 15, a second modulator 16, and a combiner 17.

The light source 13 outputs a continuous-wave light. The divider 14 divides the continuous-wave light output by the light source 13 into two lights. The first modulator 15 modulates one of the lights branched by the divider 14 with a data signal to generate a first optical signal. The second modulator 16 modulates the other optical branched by the divider 14 with a data signal to generate a second optical signal. The combiner 17 combines the first optical signal input from the first modulator 15 and the second optical signal input from the second modulator 16 with the respective polarizations orthogonal to each other to generate a polarization multiplexing signal, and outputs the generated polarization multiplexing signal to the amplifier 12.

The amplifier 12 is an optical amplifier such as a semiconductor optical amplifier or a rare earth doped fiber optical amplifier. The amplifier 12 amplifies the polarization multiplexing signal input from the generation unit 11, and outputs the amplified polarization multiplexing signal to an optical transmission path (not illustrated).
Patent Document 1: Japanese Laid-open Patent Publication No. 62-24731
Patent Document 2: Japanese Laid-open Patent Publication No. 2002-344426
Patent Document 3: Japanese Laid-open Patent Publication No. 2008-172799
Patent Document 4: Japanese Laid-open Patent Publication No. 2007-067902

However, the conventional optical signal transmission device has a problem in that the transmission characteristics of the polarization multiplexing signal degrade as difference in optical power occurs between two optical signals contained in the polarization multiplexing signal.

For instance, in the conventional optical signal transmission device 10 illustrated in FIG. 31, the branching ratio of the two lights branched at the divider 14 may differ or the optical loss in the first modulator 15 and the optical loss in the second modulator 16 may differ. In such cases, a difference in optical power occurs between the first optical signal and the second optical signal contained in the polarization multiplexing signal output from the combiner 17. The amplifier 12 then amplifies the polarization multiplexing signal containing the first optical signal and the second optical signal with difference in optical power. The transmission characteristics of the polarization multiplexing signal thus degrade in the conventional optical signal transmission device 10.

### SUMMARY

According to an aspect of an embodiment of the invention, a optical signal transmission device includes a generation unit that generates a polarization multiplexing signal in which two optical signals, each polarization of which is orthogonal to each other, are combined; a detector that detects powers of the two optical signals contained in the polarization multiplexing signal generated by the generation unit; an amplifier that amplifies, according to each polarization of the two optical signals contained in the polarization multiplexing signal generated by the generation unit, the powers of the two optical signals; and an controller that controls a gain of the amplifier with respect to each polarization of the two optical signals so as to reduce difference in the powers of the two optical signals detected by the detector.

The object and advantages of the embodiment will be realized and attained by means of the elements and combinations particularly pointed out in the claims.

It is to be understood that both the foregoing general description and the following detailed description are exemplary and explanatory and are not restrictive of the embodiment, as claimed.

### BRIEF DESCRIPTION OF DRAWINGS

FIG. 1 is a view illustrating a configuration of a optical signal transmission device according to a first embodiment;

FIG. 2 is a view describing one example of a process performed by a optical amplification device according to the first embodiment;

FIG. 3 is a view describing the effects of the optical signal transmission device according to the first embodiment;

FIG. 4 is a view illustrating a configuration of a optical signal transmission device according to a variant of the first embodiment;

FIG. 5 is a view illustrating a configuration of a optical signal transmission device according to a second embodiment;

FIG. 6 is a view describing one example of the polarization dependent gain property of an SOA;

FIG. 7 is a view illustrating one example of the drive current storage;

FIG. 8 is a flowchart illustrating the processing procedures of the optical amplification device according to the second embodiment;

FIG. 9 is a view illustrating a configuration of a optical signal transmission device according to a third embodiment;

FIG. 10 is a view illustrating a configuration of a optical signal transmission device according to a fourth embodiment;

FIG. 11 is a view illustrating a configuration of a optical signal transmission device according to a fifth embodiment;

FIG. 12 is a flowchart illustrating the processing procedure of the optical amplification device according to the fifth embodiment;

FIG. 13 is a view illustrating a configuration of a optical signal transmission device according to a sixth embodiment;

FIG. 14 is a flowchart illustrating the processing procedure of the optical amplification device according to the sixth embodiment;

FIG. 15 is a view illustrating a configuration of a optical signal transmission device according to a seventh embodiment;

FIG. 16 is a flowchart illustrating the processing procedure of the optical amplification device according to the seventh embodiment;

FIG. 17 is a view illustrating a configuration of a optical signal transmission device according to an eighth embodiment;

FIG. 18 is a view illustrating one example of a drive current storage;

FIG. 19 is a flowchart illustrating the processing procedure of the optical amplification device according to the eighth embodiment;

FIG. 20 is a view illustrating a configuration of a optical signal transmission device according to a ninth embodiment;

FIG. 21 is a view describing the polarization hole burning phenomenon that occurs in the EDF;

FIG. 22 is a view describing the polarization dependent gain property generated in the EDF;

FIG. 23 is a view illustrating one example of a polarization rotation amount storage;

FIG. 24 is a flowchart illustrating the processing procedure of the optical amplification device according to the ninth embodiment;

FIG. 25 is a view illustrating a configuration of a optical signal transmission device according to a tenth embodiment;

FIG. 26 is a flowchart illustrating the processing procedure of the optical amplification device according to the tenth embodiment;

FIG. 27 is a view illustrating a configuration of a optical signal transmission device according to an eleventh embodiment;

FIG. 28 is a view illustrating one example of an excitation optical power storage;

FIG. 29 is a flowchart illustrating the processing procedure of the optical amplification device according to the eleventh embodiment;

FIG. 30 is a view describing another configuration example of the optical signal transmission device illustrated in the second to eighth embodiments; and

FIG. 31 is a view illustrating a configuration of a conventional optical signal transmission device that employs the polarization multiplexing method.

### DESCRIPTION OF EMBODIMENTS

Preferred embodiments of the present invention will be explained with reference to accompanying drawings. The following embodiments do not intend to limit the optical signal transmission device, the optical amplification device, the optical attenuation device, and the optical signal transmission method disclosed in the present application.

### [a] First Embodiment

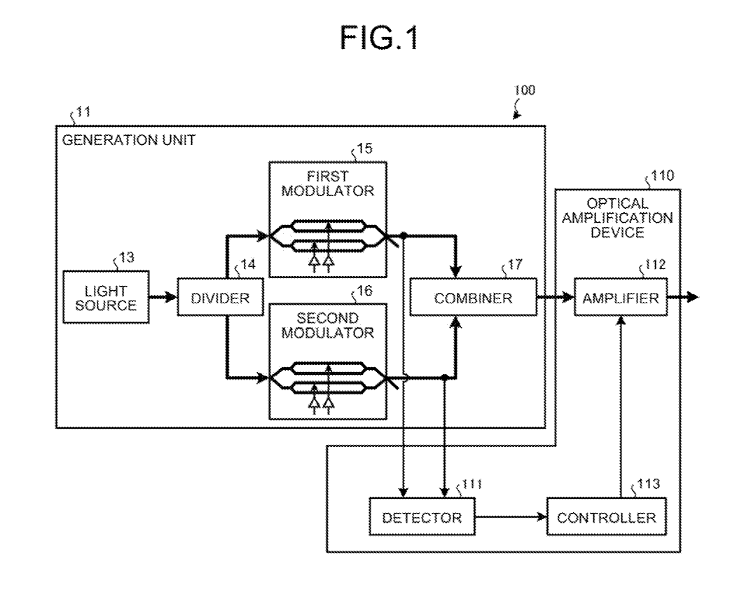

First, the configuration of an optical signal transmission device according to a first embodiment will be described. FIG. 1 is a view illustrating a configuration of an optical signal transmission device 100 according to a first embodiment. As illustrated in the figure, the optical signal transmission device 100 according to the first embodiment includes a generation unit 11 and a optical amplification device 110. The generation unit 11 generates a polarization multiplexing signal in which a first optical signal and a second optical signal, each polarization of which is orthogonal to each other, are combined.

The optical amplification device 110 includes a detector 111, an amplifier 112, and an controller 113. The detector 111 detects the powers of the first optical signal and the second optical signal contained in the polarization multiplexing signal generated by the generation unit 11. The amplifier 112 amplifies, by a gain different according to each polarization of the first optical signal and the second optical signal contained in the polarization multiplexing signal generated by the generation unit 11, the powers of the first optical signal and the second optical signal. The controller 113 controls the magnitude relationship of the power of the optical signal of each polarization input to the amplifier 112 and the gain with respect to each polarization of the amplifier 112 so that the difference in powers of the first optical signal and the second optical signal detected by the detector 111 reduces. In the other words, the controller 113 controls the gain of the amplifier with respect to each polarization of the two optical signals so as to reduce difference in the powers of the two optical signals detected by the detector 111. In the following description, the optical signal with smaller power of the first optical signal and the second optical signal contained in the polarization multiplexing signal is called a small power signal, and the optical signal with larger power of the first optical signal and the second optical signal contained in the polarization multiplexing signal is called a large power signal.

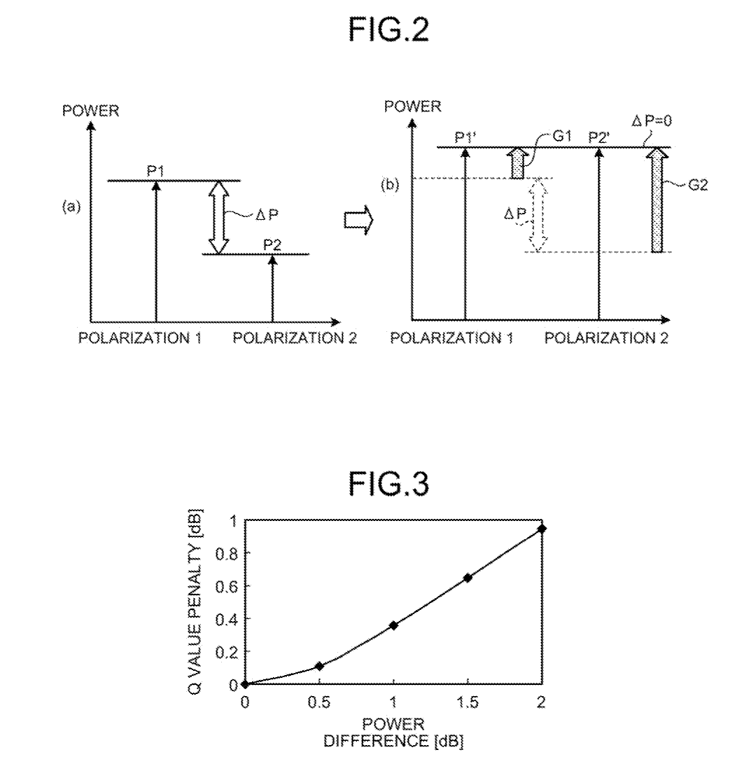

One example of a process performed by the optical amplification device 110 arranged in the optical signal transmission device 100 according to the first embodiment will be described using FIG. 2. FIG. 2 is a view describing one example of a process performed by the optical amplification device 110 according to the first embodiment. FIG. 2(a) illustrates the power P1 of the first optical signal S1 and the power P2 of the second optical signal S2 before the amplification by the optical amplification device 110. FIG. 2(b) illustrates the power P1′ of the first optical signal S1 and the power P2′ of the second optical signal S2 after the amplification by the optical amplification device 110.

As illustrated in FIG. 2(a), the optical amplification device 110 detects the power P1 of the first light signal S1 and the power P2 of the second optical signal S2 contained in the polarization multiplexing signal in the detector 111. Since the power P1 of the first optical signal S1 is larger than the power P2 of the second optical signal S2, the first optical signal S1 corresponds to the large power signal and the second optical signal S2 corresponds to the small power signal.

The optical amplification device 110 amplifies, by a gain different according to each polarization of the first optical signal and the second optical signal contained in the polarization multiplexing signal generated by the generation unit 11, the powers of the first optical signal and the second optical signal in the amplifier 112. For instance, the amplifier 112 amplifies the optical signal S1 of the first polarization at a gain G1 corresponding to the first polarization, and amplifies the optical signal S2 of the second polarization at a gain G2 corresponding to the second polarization. Assume here that the gain G2 corresponding to the second polarization is greater than the gain G1 corresponding to the first polarization.

The optical amplification device 110 then controls the magnitude relationship of the power of the optical signal of each polarization input to the amplifier 112 and the gain with respect to each polarization of the amplifier 112 such that the difference in power of the first optical signal and the second optical signal reduces by the controller 113. In the example of FIG. 2(b), the controller 113 amplifies the first optical signal or the large power signal at the gain G1 by means of the amplifier 112 so that the difference ΔP in power of the first optical signal and the second optical signal reduces to zero. The controller 113 also amplifies the second optical signal or the small power signal at the gain G2 greater than the gain G1 by means of the amplifier 112.

When difference in power arises between two optical signals contained in the polarization multiplexing signal, the optical amplification device 110 can reduce the difference in power. In the example of FIG. 2(b), the optical amplification device 110 can reduce the difference ΔP in optical power occurred between the first optical signal and the second optical signal contained in the polarization multiplexing signal to zero.

As described above, the optical signal transmission device 100 according to the first embodiment detects the powers of the two optical signals contained in the polarization multiplexing signal in which two optical signals, each polarization of which is orthogonal to each other, are combined. The optical signal transmission device 100 amplifies, by the gain different according to each polarization of the two optical signals contained in the polarization multiplexing signal generated by the generation unit 11, the powers of the two optical signals. The optical signal transmission device 100 controls the gain of the amplifier with respect to each polarization of the two optical signals so as to reduce difference in the powers of the two optical signals detected by the detector. Thus, the optical signal transmission device 100 can reduce the difference in power even if a difference in power arises between two optical signals contained in the polarization multiplexing signal. As a result, the optical signal transmission device 100 can enhance the transmission characteristics of the polarization multiplexing signal.

FIG. 3 is a view describing the effects of the optical signal transmission device 100 according to the first embodiment. The horizontal axis of FIG. 3 illustrates the difference in power of the two optical signals contained in the polarization multiplexing signal, and the vertical axis of FIG. 3 illustrates the Q value penalty, which is the degradation amount of the transmission characteristics of the polarization multiplexing signal. In the example of FIG. 3, assume that the polarization multiplexing Quadrature Phase-Shift Keying (QPSK) method is used. As illustrated in the figure, it can be recognized that when a power difference of about 2 dB is occurred between two optical signals contained in the polarization multiplexing signal, the Q value penalty becomes about 1 dB and the transmission characteristics of the polarization multiplexing signal degrade. The optical signal transmission device 100 according to the first embodiment can enhance the Q value penalty by about 1 dB by reducing the power difference of about 2 dB occurred between the two optical signals contained in the polarization multiplexing signal to zero.

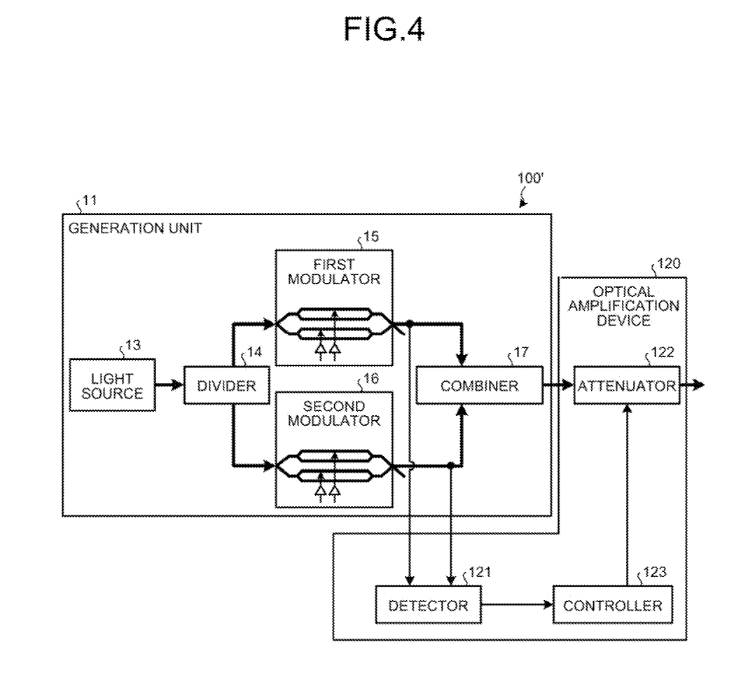

A variant of the optical signal transmission device 100 according to the first embodiment will now be described. FIG. 4 is a view illustrating a configuration of an optical signal transmission device 100′ according to a variant of the first embodiment. As illustrated in the figure, the optical signal transmission device 100′ according to the variant includes an optical attenuation device 120 in place of the optical amplification device 110 illustrated in FIG. 1. The optical attenuation device 120 includes a detector 121, an attenuator 122, and an controller 123.

The detector 121 is similar to the detector 111 illustrated in FIG. 1. The attenuator 122 attenuates, by a loss different according to each polarization of the first optical signal and the second optical signal contained in the polarization multiplexing signal generated by the generation unit 11, the powers of the first optical signal and the second optical signal. The controller 123 controls the magnitude relationship of the power of the optical signal of each polarization input to the attenuator 122 and the loss with respect to each polarization of the attenuator 122 such that the difference in power of the first optical signal and the second optical signal detected by the detector 121 reduces. In the other words, the controller 123 controls the loss of the attenuator with respect to each polarization of the two optical signals so as to reduce difference in the powers of the two optical signals detected by the detector 121.

Thus, similar to the first embodiment, the optical signal transmission device 100′ according to the variant can reduce the power difference even if difference in power is occurred between two optical signals contained in the polarization multiplexing signal. As a result, the optical signal transmission device 100′ can enhance the transmission characteristics of the polarization multiplexing signal.

### [b] Second Embodiment

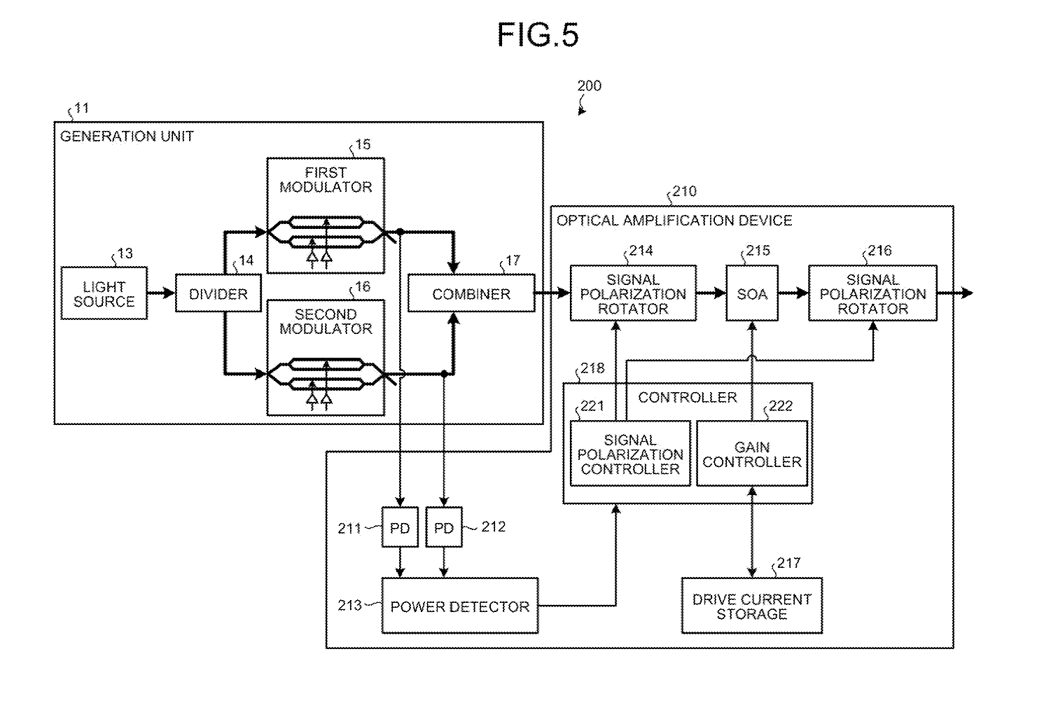

Now, the configuration of an optical signal transmission device according to a second embodiment will be described. FIG. 5 is a view illustrating a configuration of a optical signal transmission device 200 according to a second embodiment. As illustrated in the figure, the optical signal transmission device 200 includes the generation unit 11 and a optical amplification device 210.

The generation unit 11 generates a polarization multiplexing signal in which a first optical signal and a second optical signal, each polarization of which is orthogonal to each other, are combined. In the following description, the polarization of the first optical signal is assumed to be horizontal, and the first optical signal in which the polarization is horizontal is referred to as a horizontal polarization signal. The polarization of the second optical signal is assumed to be vertical, and the second optical signal in which the polarization is vertical is referred to as a vertical polarization signal.

The optical amplification device 210 includes a PD (Photo Detector) 211, a PD 212, a power detector 213, a signal polarization rotator 214, a semiconductor optical amplifier (SOA) 215, a signal polarization rotator 216, a drive current storage 217, and a controller 218.

The PD 211 converts the horizontal polarization signal output from the first modulator 15 to the combiner 17 in the generation unit 11 to an electric signal, and outputs the same to the power detector 213. The PD 212 converts the vertical polarization signal output from the second modulator 16 to the combiner 17 in the generation unit 11 to an electric signal, and outputs the same to the power detector 213.

The power detector 213 detects the powers of the horizontal polarization signal and the vertical polarization signal contained in the polarization multiplexing signal. Specifically, the power detector 213 detects the powers of the horizontal polarization signal and the vertical polarization signal using the electric signals input from the PD 211 and the PD 212. The power detector 213 then outputs the detected powers of the horizontal polarization signal and the vertical polarization signal to the controller 218.

The signal polarization rotator 214 rotates the polarizations of the horizontal polarization signal and the vertical polarization signal contained in the polarization multiplexing signal input from the generation unit 11. Specifically, the signal polarization rotator 214 rotates the polarizations of the horizontal polarization signal and the vertical polarization signal by 0° or 90° according to the control by a signal polarization controller 221, to be described later, of the controller 218.

The SOA 215 is a semiconductor optical amplifier having a property in which the gain corresponding to one of the polarizations of the horizontal polarization or the vertical polarization is greater than the gain corresponding to the other polarization (hereinafter also referred to as “polarization dependent gain property”). In the SOA 215 according to the present example, the gain corresponding to the vertical polarization is assumed to be greater than the gain corresponding to the horizontal polarization. The SOA 215 also changes its gain according to the drive current supplied from a gain controller 222, to be described later, of the controller 218.

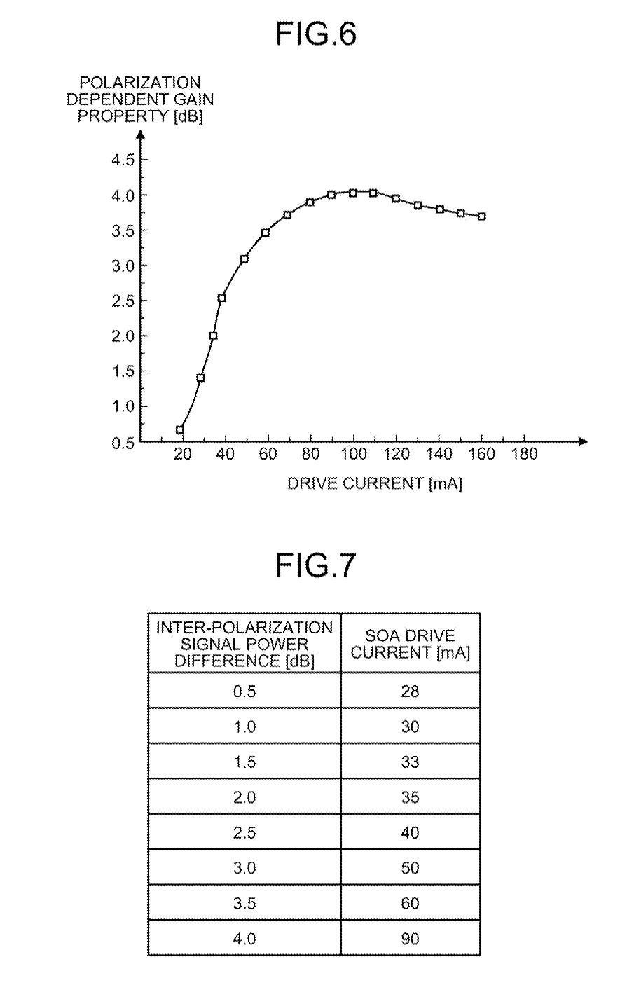

FIG. 6 is a view describing one example of the polarization dependent gain property of the SOA 215. The horizontal axis of FIG. 6 illustrates the drive current supplied to the SOA 215, and the vertical axis of FIG. 6 illustrates the polarization dependent gain or a value obtained by subtracting the gain corresponding to the horizontal polarization from the gain corresponding to the vertical polarization. As illustrated in the figure, the gain corresponding to the vertical polarization is greater than the gain corresponding to the horizontal polarization in the SOA 215, and the polarization dependent gain constantly illustrates a positive value irrespective of the drive current. Therefore, if the polarization of the optical signal input from the signal polarization rotator 214 is a vertical polarization, such optical signal of vertical polarization is amplified at a gain greater than that for the optical signal of horizontal polarization.

When the drive current supplied to the SOA 215 is changed between about 20 mA to 90 mA, the polarization dependent gain of the SOA 215 changes between about 0.5 to 4 dB. The SOA 215 thus can reduce the power difference of a maximum of 4 dB occurred between the input optical signal of vertical polarization and the optical signal of horizontal polarization.

Returning back to the description of FIG. 5, the signal polarization rotator 216 rotates the polarizations of the horizontal polarization signal and the vertical polarization signal contained in the polarization multiplexing signal input from the SOA 215. Specifically, the signal polarization rotator 216 rotates the polarizations of the horizontal polarization signal and the vertical polarization signal by 0° or −90° according to the control by the signal polarization controller 221, to be described later, of the controller 218.

The drive current storage 217 stores the drive current supplied from the controller 218 to the SOA 215. FIG. 7 is a view illustrating one example of the drive current storage 217. As illustrated in the figure, the drive current storage 217 stores items such as “inter-polarization signal power difference” and “SOA drive current” in correspondence to each other. The “inter-polarization power difference” refers to the power difference of the horizontal polarization signal and the vertical polarization signal contained in the polarization multiplexing signal. The “SOA drive current” refers to the drive current of the SOA 215 defined in advance so that the inter-polarization signal power difference reduces to smaller than or equal to a predetermined value. The predetermined value is a value as close as possible to zero, and for example, is a value smaller than 0.5 dB.

The “SOA drive current” in the drive current storage 217 is set by designers using the polarization dependent gain property of the SOA 215 illustrated in FIG. 6. For instance, consider a case in which the power difference of the horizontal polarization signal and the vertical polarization signal is about 3 dB. In this case, the designers set “50 mA” or the drive current at which the polarization dependent gain of the SOA 215 becomes 3 dB as the “SOA drive current” corresponding to the “inter-polarization signal power difference”, “3 dB” using the polarization dependent gain property of the SOA 215 illustrated in FIG. 6.

The “SOA drive current” increases as the “inter-polarization signal power difference” becomes larger. This means that when the power difference of the horizontal polarization signal and the vertical polarization signal is increased, the increased power difference can be reduced by increasing the drive current to supply to the SOA 215.

Returning back to the description of FIG. 5, the controller 218 controls the signal polarization rotator 214, the SOA 215, and the signal polarization rotator 216. Specifically, the controller 218 includes the signal polarization controller 221 and the gain controller 222.

The signal polarization controller 221 controls the signal polarization rotator 214 and the signal polarization rotator 216 based on the powers of the horizontal polarization signal and the vertical polarization signal input from the power detector 213. Specifically, when receiving the powers of the horizontal polarization signal and the vertical polarization signal from the power detector 213, the signal polarization controller 221 calculates the power difference of the horizontal polarization signal and the vertical polarization signal. The signal polarization controller 221 then determines whether or not the calculated power difference of the horizontal polarization signal and the vertical polarization signal is smaller than or equal to a predetermined value, and terminates the process if the power difference of the horizontal polarization signal and the vertical polarization signal is smaller than or equal to the predetermined value. The predetermined value is a value as close as possible to zero, and for example, is a value smaller than 0.5 dB. The signal polarization controller 221 controls the signal polarization rotators 214, 216 so that the polarization of the small power signal of the horizontal polarization signal and the vertical polarization signal and the polarization of the large power signal match the vertical polarization and the horizontal polarization, respectively, in the SOA 215, when the power difference exceeds the predetermined value.

For instance, consider a case in which the horizontal polarization signal is the large power signal and the vertical polarization signal is the small power signal, that is, the power of the horizontal polarization signal is larger than the power of the vertical polarization signal. In this case, the signal polarization controller 221 sets the rotation amounts of the polarizations of the signal polarization rotators 214, 216 both to 0° such that the polarization of the horizontal polarization signal and the polarization of the vertical polarization signal match the horizontal polarization and the vertical polarization in the SOA 215. In the SOA 215 according to the present example, the gain corresponding to the vertical polarization is greater than the gain corresponding to the horizontal polarization. Therefore, in the SOA 215, the vertical polarization signal or the small power signal is amplified with the gain greater than that for the horizontal polarization signal or the large power signal. The power difference of the vertical polarization signal and the horizontal polarization signal thus reduces.

For instance, consider a case in which the horizontal polarization signal is the small power signal and the vertical polarization signal is the large power signal, that is, the power of the horizontal polarization signal is smaller than the power of the vertical polarization signal. In this case, the signal polarization controller 221 sets the rotation amounts of the polarizations of the signal polarization rotators 214, 216 to 90°, −90°, respectively, such that the polarization of the horizontal polarization signal and the polarization of the vertical polarization signal match the vertical polarization and the horizontal polarization in the SOA 215. In the SOA 215 according to the present example, the gain corresponding to the vertical polarization is greater than the gain corresponding to the horizontal polarization. Therefore, in the SOA 215, the horizontal polarization signal or the small power signal is amplified with the gain greater than that for the vertical polarization signal or the large power signal. The power difference of the horizontal polarization signal and the vertical polarization signal thus reduces.

The gain controller 222 controls the polarization dependent gain of the SOA 215 based on the powers of the horizontal polarization signal and the vertical polarization signal input from the power detector 213. Specifically, when receiving the powers of the horizontal polarization signal and the vertical polarization signal input from the power detector 213, the gain controller 222 calculates the power difference of the horizontal polarization signal and the vertical polarization signal. The gain controller 222 then reads out the drive current corresponding to the calculated power difference from the drive current storage 217, and supplies the read drive current to the SOA 215. The gain controller 222 then can change the drive current to be supplied to the SOA 215 between about 20 and 90 mA, and can change the polarization dependent gain of the SOA 215 between about 0.5 and 4 dB. As a result, even if the power difference of the horizontal polarization signal and the vertical polarization signal is temporally increased, the gain controller 222 can reduce the temporally increased power difference by changing the polarization dependent gain of the SOA 215.

The PD 211, the PD 212, and the power detector 213 illustrated in FIG. 5 are examples of the detector 111 illustrated in FIG. 1. The SOA 215 illustrated in FIG. 5 is an example of the amplifier 112 illustrated in FIG. 1. The signal polarization rotator 214, the signal polarization rotator 216, and the controller 218 illustrated in FIG. 5 are examples of the controller 113 illustrated in FIG. 1.

The power detector 213 and the controller 218 illustrated in FIG. 5 are integrated circuits of Application Specific Integrated Circuit (ASIC), Field Programmable Gate Array (FPGA), and the like. The drive current storage 217 illustrated in FIG. 5 is a semiconductor memory element such as Random Access Memory (RAM), Read Only Memory (ROM), and flash memory.

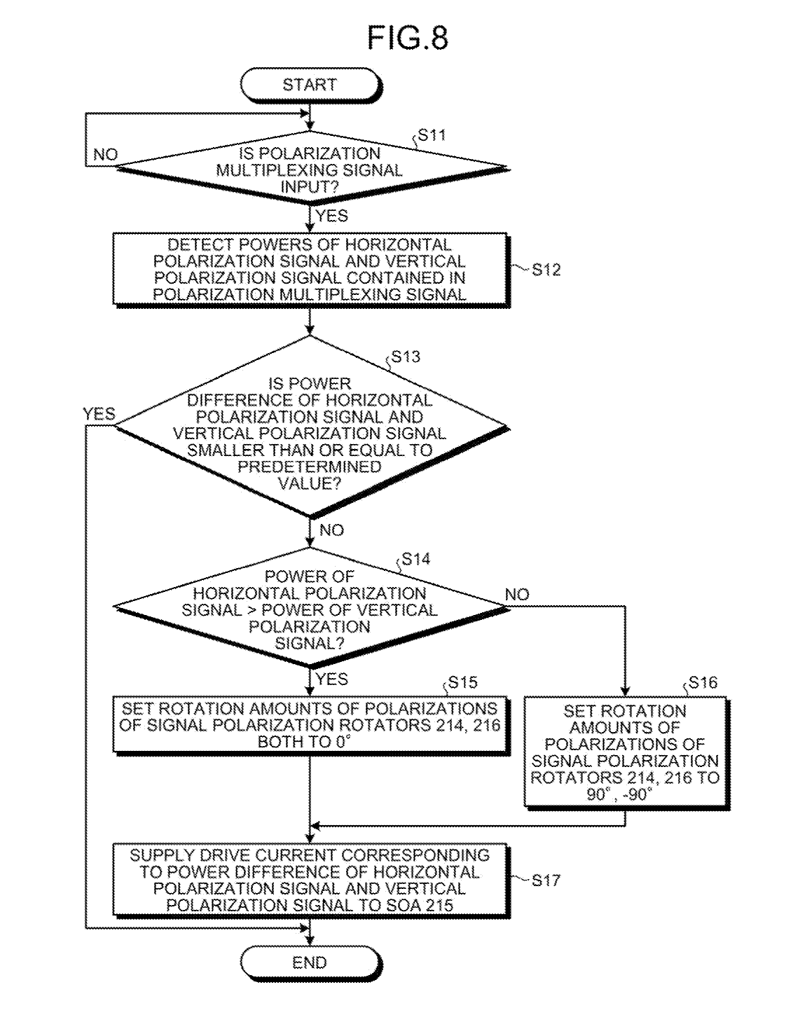

One example of a process in which the optical amplification device 210 arranged in the optical signal transmission device 200 illustrated in FIG. 5 amplifies the polarization multiplexing signal and outputs to the optical transmission path will now be described. FIG. 8 is a flowchart illustrating the processing procedures of the optical amplification device 210 according to the second embodiment. As illustrated in the figure, the optical amplification device 210 determines whether or not the polarization multiplexing signal is input from the generation unit 11 (step S11), and waits until input (negative in step S11). When the polarization multiplexing signal is input from the generation unit 11 (positive in step S11), the power detector 213 detects the powers of the horizontal polarization signal and the vertical polarization signal contained in the polarization multiplexing signal (step S12). The power detector 213 then outputs the detected powers of the horizontal polarization signal and the vertical polarization signal to the controller 218.

The signal polarization controller 221 of the controller 218 then determines whether or not the power difference of the horizontal polarization signal and the vertical polarization signal is smaller than or equal to a predetermined value (step S13). The predetermined value here is a value as close as possible to zero and for example, is a value smaller than 0.5 dB. If the power difference of the horizontal polarization signal and the vertical polarization signal is smaller than or equal to the predetermined value (positive in step S13), the signal polarization controller 221 terminates the process. If the power difference of the horizontal polarization signal and the vertical polarization signal exceeds a predetermined value (negative in step S13), the signal polarization controller 221 compares the magnitude relationship of the power of the horizontal polarization signal and the power of the vertical polarization signal (step S14).

If the power of the horizontal polarization signal is larger than the power of the vertical polarization signal (positive in step S14), the signal polarization controller 221 sets the rotation amounts of the polarizations of the signal polarization rotators 214, 216 both to 0° (step S15). The polarization of the horizontal polarization signal and the polarization of the vertical polarization signal thus match the horizontal polarization and the vertical polarization in the SOA 215. In the SOA 215, the gain corresponding to the vertical polarization is greater than the gain corresponding to the horizontal polarization. Therefore, the vertical polarization signal or the small power signal is amplified at a gain greater than that for the horizontal polarization signal or the large power signal in the SOA 215.

If the power of the horizontal polarization signal is smaller than the power of the vertical polarization signal (negative in step S14), the signal polarization controller 221 sets the rotation amounts of the polarizations of the signal polarization rotators 214, 216 to 90°, −90°, respectively (step S16). The polarization of the horizontal polarization signal and the polarization of the vertical polarization signal thus match the vertical polarization and the horizontal polarization in the SOA 215. In the SOA 215, the gain corresponding to the vertical polarization is greater than the gain corresponding to the horizontal polarization. Therefore, the horizontal polarization signal or the small power signal is amplified at a gain greater than that for the vertical polarization signal or the large power signal in the SOA 215.

The gain controller 222 of the controller 218 then calculates the power difference of the horizontal polarization signal and the vertical polarization signal, reads out the drive current corresponding to the calculated power difference from the drive current storage 217, and supplies the drive current to the SOA 215 (step S17).

As described above, the optical signal transmission device 200 according to the second embodiment detects the powers of the horizontal polarization signal and the vertical polarization signal contained in the polarization multiplexing signal. The optical signal transmission device 200 then amplifies, by a gain different according to each polarization of the horizontal polarization signal and the vertical polarization signal contained in the polarization multiplexing signal, the powers of the horizontal polarization signal and the vertical polarization signal. The optical signal transmission device 200 controls the magnitude relationship of the power of the horizontal polarization signal and the vertical polarization signal input to the SOA 215 and the gain corresponding to the horizontal polarization and the vertical polarization of the SOA 215 such that the power difference of the horizontal polarization signal and the vertical polarization signal reduces. The optical signal transmission device 200 thus can reduce the power difference even if difference in power is occurred between the horizontal polarization signal and the vertical polarization signal contained in the polarization multiplexing signal. As a result, the optical signal transmission device 200 can enhance the transmission characteristics of the polarization multiplexing signal.

In the optical signal transmission device 200 according to the second embodiment, the SOA 215 has the polarization dependent gain property in which the gain corresponding to the vertical polarization is greater than the gain corresponding to the horizontal polarization. The optical signal transmission device 200 rotates the polarizations of the horizontal polarization signal and the vertical polarization signal such that the polarization of the large power signal of the horizontal polarization signal and the vertical polarization signal matches the horizontal polarization of the SOA 215, and the polarization of the small power signal matches the vertical polarization of the SOA 215. The optical signal transmission device 200 then can simultaneously adjust the powers of the two optical signals contained in the polarization multiplexing signal using the polarization dependent gain property which the SOA 215 originally has, so that the device configuration can be more simplified than when adjusting each power of the two optical signals.

The optical signal transmission device 200 according to the second embodiment controls the polarization dependent gain of the SOA 215 by supplying to the SOA 215 the drive current that increases as the power difference of the horizontal polarization signal and the vertical polarization signal becomes larger. Thus, even if the power difference of the horizontal polarization signal and the vertical polarization signal increased by temperature change, aging, and the like, the optical signal transmission device 200 can reduce the power difference increased by temperature change, aging, and the like by changing the polarization dependent gain of the SOA 215. As a result, the optical signal transmission device 200 can maintain satisfactory transmission characteristics of the polarized multiplexing signal for a long period of time.

### [c] Third Embodiment

In the second embodiment, an example in which the powers of the optical signals are detected using the optical signals output from the first modulator 15 and the second modulator 16 has been described. However, the powers of the optical signals may be detected using a phase conjugate light of the optical signals output from the first modulator 15 and the second modulator 16. In the third embodiment, an example of detecting the powers of the optical signals using the phase conjugate light of the optical signals output from the first modulator 15 and the second modulator 16 will be described.

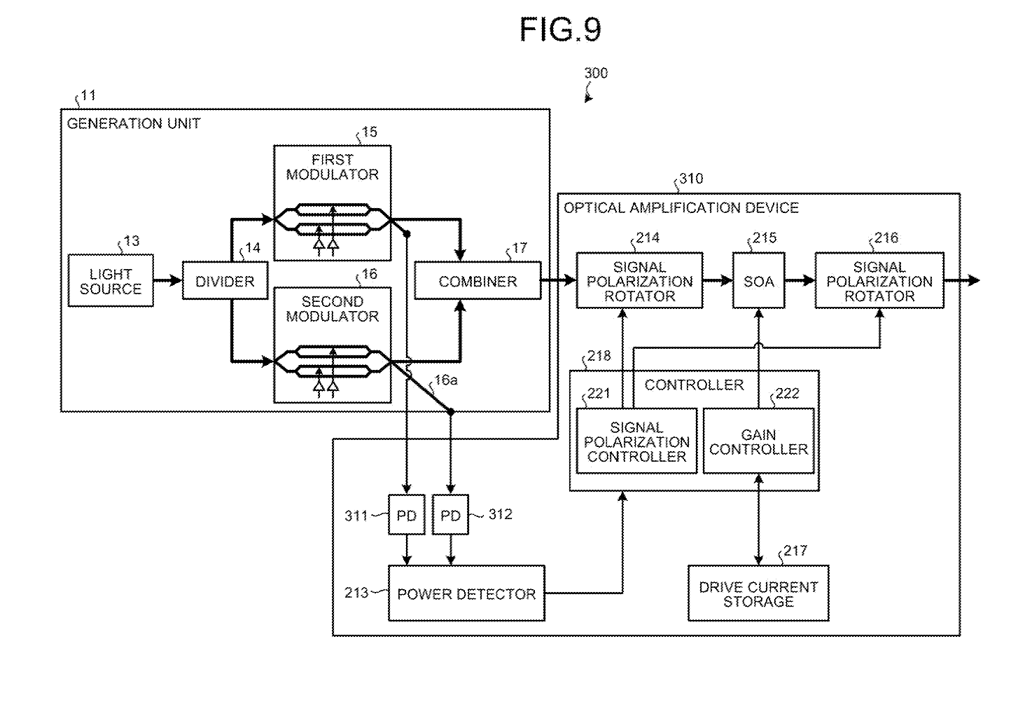

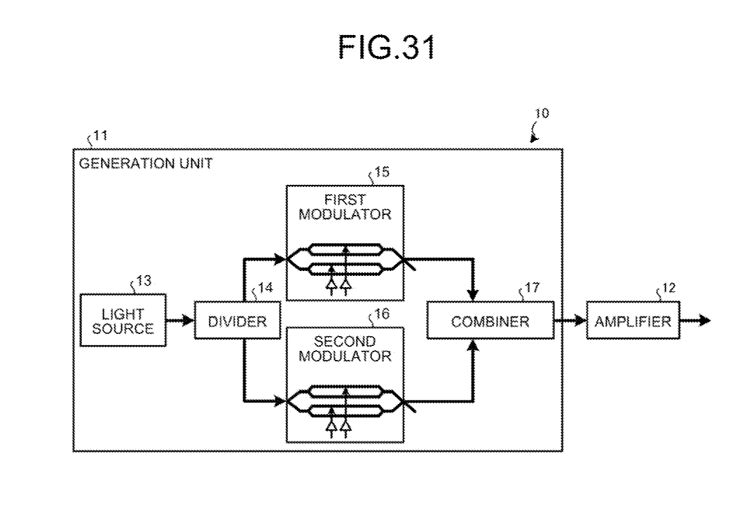

FIG. 9 is a view illustrating a configuration of an optical signal transmission device 300 according to the third embodiment. As illustrated in the figure, the optical signal transmission device 300 includes the generation unit 11 and an optical amplification device 310. The generation unit 11 is similar to the generation unit 11 illustrated in FIG. 31.

The optical amplification device 310 includes a PD 311, a PD 312, the power detector 213, the signal polarization rotator 214, the SOA 215, the signal polarization rotator 216, the drive current storage 217, and the controller 218. The power detector 213, the signal polarization rotator 214, and the SOA 215 are processing units similar to the power detector 213, the signal polarization rotator 214, and the SOA 215 illustrated in FIG. 5. The signal polarization rotator 216, the drive current storage 217, and the controller 218 are processing units similar to the signal polarization rotator 216, the drive current storage 217, and the controller 218 illustrated in FIG. 5.

The PD 311 converts a phase conjugate light output from a port 15a of the first modulator 15 in the generation unit 11 to an electric signal, and outputs the same to the power detector 213. The phase conjugate light output from the port 15a of the first modulator 15 is a light having a reversed phase from the horizontal polarization signal output from the first modulator 15 to the combiner 17, and has the same power as the horizontal polarization signal. The phase conjugate light is normally not used as an optical signal. The PD 311 outputs the phase conjugate light, which is normally not used as the optical signal, to the power detector 213 and does not output the horizontal polarization signal itself to the power detector 213. Therefore, the loss of the horizontal polarization signal itself output from the first modulator 15 to the combiner 17 can be reduced.

The PD 312 converts a phase conjugate light output from a port 16a of the second modulator 16 in the generation unit 11 to an electric signal, and outputs the same to the power detector 213. The phase conjugate light output from the port 16a of the second modulator 16 is a light having a reversed phase from the vertical polarization signal output from the second modulator 16 to the combiner 17, and has the same power as the vertical polarization signal. The phase conjugate light is normally not used as an optical signal. The PD 312 outputs the phase conjugate light, which is normally not used as the optical signal, to the power detector 213 and does not output the vertical polarization signal itself to the power detector 213. Therefore, the loss of the vertical polarization signal itself output from the second modulator 16 to the combiner 17 can be reduced. The PD 311, the PD 312, and the power detector 213 illustrated in FIG. 9 are examples of the detector 111 illustrated in FIG. 1.

As described above, the optical signal transmission device 300 according to the third embodiment detects the power of the optical signal using the phase conjugate light of the optical signals output from the first modulator 15 and the second modulator 16. Thus, the optical signal transmission device 300 can reduce the loss of the horizontal polarization signal and the vertical polarization signal contained in the polarization multiplexing signal. As a result, the optical signal transmission device 300 can further enhance the transmission characteristics of the polarization multiplexing signal.

### [d] Fourth Embodiment

In the second embodiment, an example of detecting the powers of the horizontal polarization signal and the vertical polarization signal of before being combined by the combiner 17 is illustrated. However, the powers of the horizontal polarization signal and the vertical polarization signal of after being combined by the combiner 17 may be detected. In the fourth embodiment, an example of detecting the powers of the horizontal polarization signal and the vertical polarization signal of after being combined by the combiner 17 is illustrated.

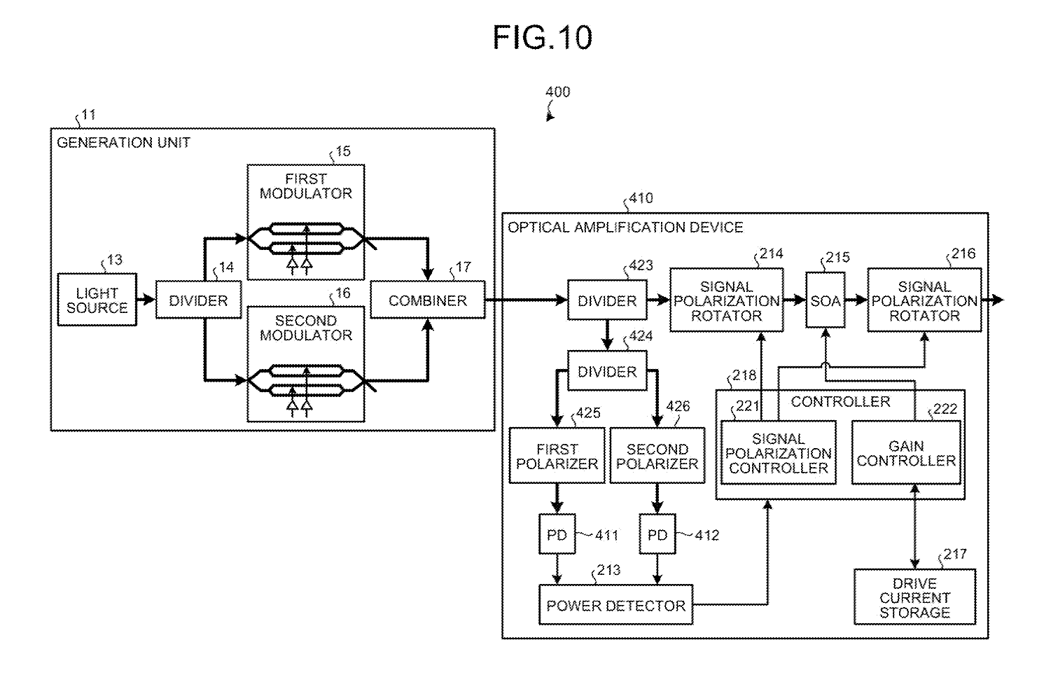

FIG. 10 is a view illustrating a configuration of an optical signal transmission device 400 according to a fourth embodiment. As illustrated in the figure, the optical signal transmission device 400 includes the generation unit 11 and an optical amplification device 410. The generation unit 11 is similar to the generation unit 11 illustrated in FIG. 31.

The optical amplification device 410 includes a divider 423, a divider 424, a first polarizer 425, a second polarizer 426, a PD 411, a PD 412, the power detector 213, the signal polarization rotator 214, the SOA 215, the signal polarization rotator 216, the drive current storage 217, and the controller 218. The power detector 213, the signal polarization rotator 214, and the SOA 215 are processing units similar to the power detector 213, the signal polarization rotator 214, and the SOA 215 illustrated in FIG. 5. The signal polarization rotator 216, the drive current storage 217, and the controller 218 are processing units similar to the signal polarization rotator 216, the drive current storage 217, and the controller 218 illustrated in FIG. 5.

The divider 423 divides the polarization multiplexing signal output from the combiner 17 of the generation unit 11 to two polarization multiplexing signals, and outputs one of the branched polarization multiplexing signals to the signal polarization rotator 214 and outputs the other polarization multiplexing signal to the divider 424. The divider 424 divides the polarization multiplexing signal input from the divider 423 to two polarization multiplexing signals, and outputs one of the branched polarization multiplexing signals to the first polarizer 425 and outputs the other branched polarization multiplexing signal to the second polarizer 426.

The first polarizer 425 transmits only the horizontal polarization signal of the horizontal polarization signal and the vertical polarization signal contained in the polarization multiplexing signal input from the divider 424, and outputs the transmitted horizontal polarization signal to the PD 411. The second polarizer 426 transmits only the vertical polarization signal of the horizontal polarization signal and the vertical polarization signal contained in the polarization multiplexing signal input from the polarization multiplexing signal input from the divider 424, and outputs the transmitted vertical polarization signal to the PD 412.

The PD 411 converts the horizontal polarization signal input from the first polarizer 425 to an electric signal, and outputs the same to the power detector 213. The PD 412 converts the vertical polarization signal input from the second polarizer 426 to an electric signal, and outputs the same to the power detector 213. The divider 423, the divider 424, the first polarizer 425, the second polarizer 426, the PD 411, the PD 412, and the power detector 213 illustrated in FIG. 10 are examples of the detector 111 illustrated in FIG. 1.

As described above, the optical signal transmission device 400 according to the fourth embodiment detects the powers of the horizontal polarization signal and the vertical polarization signal of after being combined by the combiner 17. Thus, even when power difference arises between the horizontal polarization signal and the vertical polarization signal of after being combined by the combiner 17, the optical signal transmission device 400 can reduce the power difference. As a result, the optical signal transmission device 400 can enhance the transmission characteristics of the polarization multiplexing signal.

### [e] Fifth Embodiment

In the second to fourth embodiments, an example of detecting the powers of two optical signals contained in the polarization multiplexing signal of before the amplification by the SOA 215 and controlling the polarization dependent gain of the SOA 215 by supplying the drive current defined in advance in correspondence to the detected power difference to the SOA 215. However, the powers of two optical signals contained in the polarization multiplexing signal of after the amplification by the SOA 215 may be detected, and the polarization dependent gain of the SOA 215 may be feedback controlled using the detected power. In the fifth embodiment, an example of detecting the powers of two optical signals contained in the polarization multiplexing signal of after the amplification by the SOA 215, and feedback controlling the polarization dependent gain of the SOA 215 using the detected power will be described.

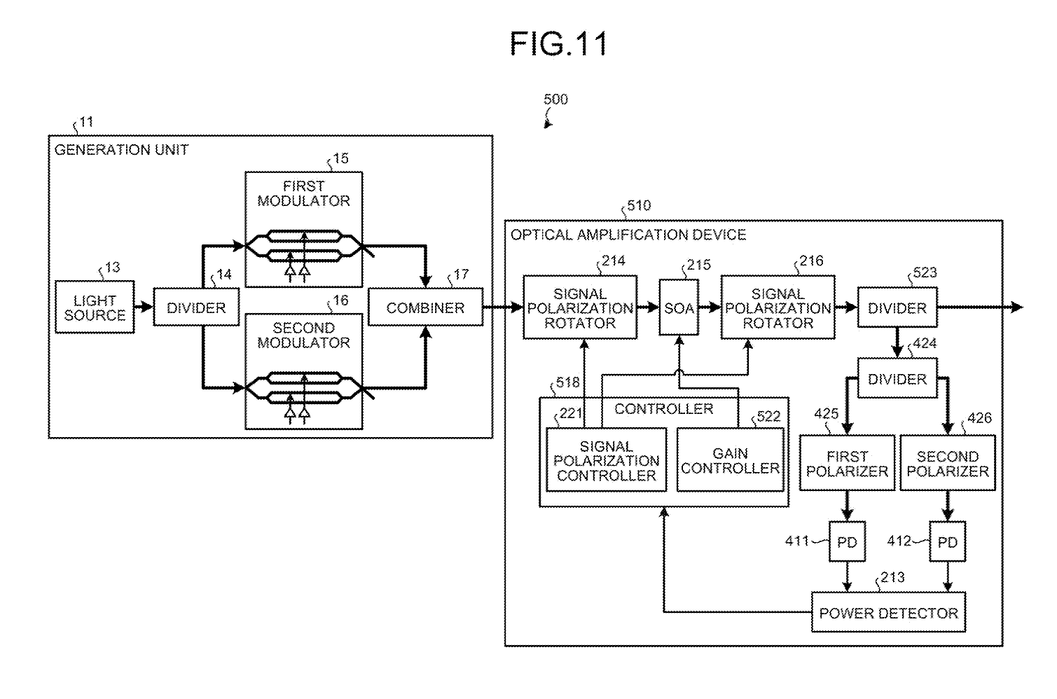

FIG. 11 is a view illustrating a configuration of an optical signal transmission device 500 according to a fifth embodiment. As illustrated in the figure, the optical signal transmission device 500 includes the generation unit 11 and an optical amplification device 510. The generation unit 11 is similar to the generation unit 11 illustrated in FIG. 31.

The optical amplification device 510 includes a divider 523, the divider 424, the first polarizer 425, the second polarizer 426, the PD 411, the PD 412, the power detector 213, the signal polarization rotator 214, the SOA 215, the signal polarization rotator 216, and a controller 518. The power detector 213, the signal polarization rotator 214, and the signal polarization rotator 216 are processing units similar to the power detector 213, the signal polarization rotator 214, and the signal polarization rotator 216 illustrated in FIG. 5. The divider 424, the first polarizer 425, the second polarizer 426, the PD 411, and the PD 412 are processing units similar to the divider 424, the first polarizer 425, the second polarizer 426, the PD 411, and the PD 412 illustrated in FIG. 10.

The divider 523 divides the polarization multiplexing signal output from the signal polarization rotator 216 on the post-stage side than the SOA 215 to two polarization multiplexing signals, and outputs one of the branched polarization multiplexing signals to the optical transmission path (not illustrated) and outputs the other polarization multiplexing signal to the divider 424. The polarization multiplexing signal output to the divider 424 is input to the power detector 213 through the divider 424, the first polarizer 425, the second polarizer 426, the PD 411, and the PD 412. The power detector 213 detects the powers of the horizontal polarization signal and the vertical polarization signal contained in the polarization multiplexing signal of after the amplification by the SOA 215, and outputs the detected power to the controller 518.

The controller 518 controls the signal polarization rotator 214, the SOA 215, and the signal polarization rotator 216. Specifically, the controller 518 includes the signal polarization controller 221 and a gain controller 522. The signal polarization controller 221 is similar to the signal polarization controller 221 illustrated in FIG. 5.

The gain controller 522 feedback controls the gain of the SOA 215 using the powers of the horizontal polarization signal and the vertical polarization signal input from the power detector 213. Specifically, when receiving the powers of the horizontal polarization signal and the vertical polarization signal from the power detector 213, the gain controller 522 calculates the power difference of the horizontal polarization signal and the vertical polarization signal. The gain controller 522 dynamically controls the drive current to supply to the SOA 215 so that the calculated power difference becomes a predetermined value, and supplies the adjusted drive current to the SOA 215. The gain controller 522 can accurately reduce the power difference of the horizontal polarization signal and the vertical polarization signal even if the polarization dependent gain property of the SOA 215 is changed due to temperature fluctuation, aging, and the like.

The divider 523, the divider 424, the first polarizer 425, the second polarizer 426, the PD 411, the PD 412, and the power detector 213 illustrated in FIG. 11 are examples of the detector 111 illustrated in FIG. 1. The signal polarization rotator 214, the signal polarization rotator 216, and the controller 518 illustrated in FIG. 11 are examples of the controller 113 illustrated in FIG. 1. The controller 518 illustrated in FIG. 11 is an integrated circuit such as an ASIC or an FPGA.

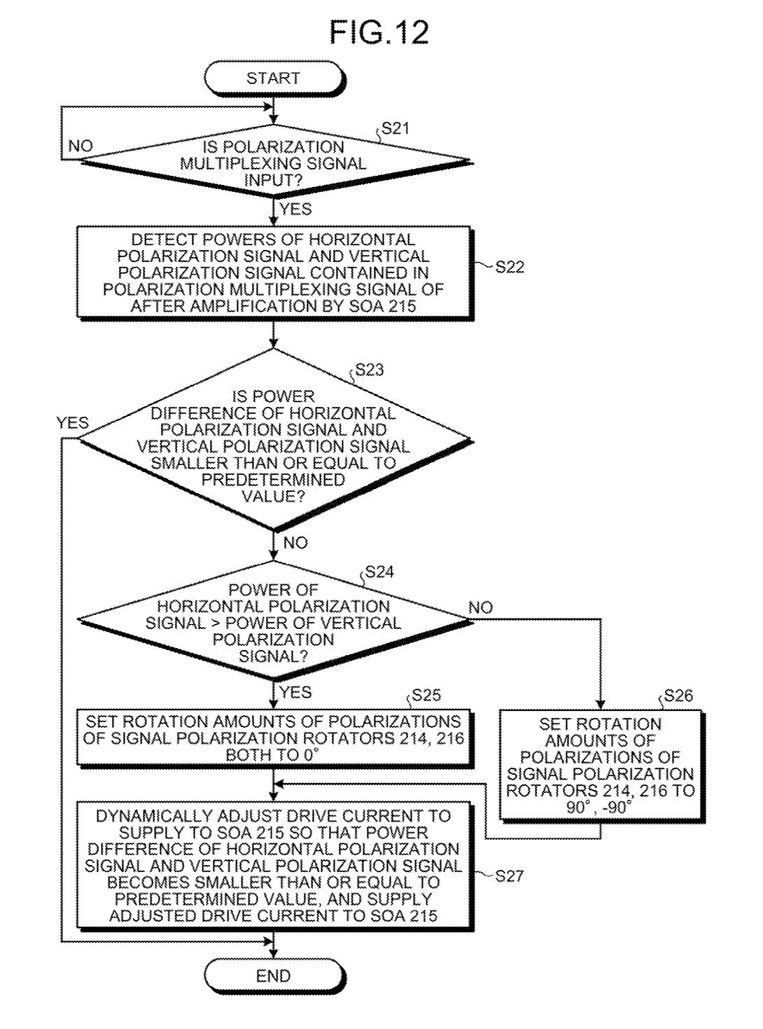

An example of a process in which the optical amplification device 510 arranged in the optical signal transmission device 500 illustrated in FIG. 11 amplifies the polarization multiplexing signal and outputs the same to the optical transmission path will now be described. FIG. 12 is a flowchart illustrating the processing procedure of the optical amplification device 510 according to the fifth embodiment. As illustrated in the figure, the optical amplification device 510 determines whether or not the polarization multiplexing signal is input from the generation unit 11 (step S21), and waits until input (negative in step S21). When the polarization multiplexing signal is input from the generation unit 11 (positive in step S21), the power detector 213 detects the powers of the horizontal polarization signal and the vertical polarization signal contained in the polarization multiplexing signal of after the amplification by the SOA 215 (step S22). The power detector 213 then outputs the detected powers of the horizontal polarization signal and the vertical polarization signal to the controller 518.

The signal polarization controller 221 of the controller 518 then determines whether or not the power difference of the horizontal polarization signal and the vertical polarization signal is smaller than or equal to a predetermined value (step S23). The predetermined value here is a value as close as possible to zero and for example, is a value smaller than 0.5 dB. If the power difference of the horizontal polarization signal and the vertical polarization signal is smaller than or equal to the predetermined value (positive in step S23), the signal polarization controller 221 terminates the process. If the power difference of the horizontal polarization signal and the vertical polarization signal exceeds a predetermined value (negative in step S23), the signal polarization controller 221 compares the magnitude relationship of the power of the horizontal polarization signal and the power of the vertical polarization signal (step S24).

If the power of the horizontal polarization signal is larger than the power of the vertical polarization signal (positive in step S24), the signal polarization controller 221 sets the rotation amounts of the polarizations of the signal polarization rotators 214, 216 both to 0° (step S25). The polarization of the horizontal polarization signal and the polarization of the vertical polarization signal thus match the horizontal polarization and the vertical polarization in the SOA 215. In the SOA 215, the gain corresponding to the vertical polarization is greater than the gain corresponding to the horizontal polarization. Therefore, the vertical polarization signal or the small power signal is amplified at a gain greater than that for the horizontal polarization signal or the large power signal in the SOA 215.

If the power of the horizontal polarization signal is smaller than the power of the vertical polarization signal (negative in step S24), the signal polarization controller 221 sets the rotation amounts of the polarizations of the signal polarization rotators 214, 216 to 90°, −90°, respectively (step S26). The polarization of the horizontal polarization signal and the polarization of the vertical polarization signal thus match the vertical polarization and the vertical polarization in the SOA 215. In the SOA 215, the gain corresponding to the vertical polarization is greater than the gain corresponding to the horizontal polarization. Therefore, the horizontal polarization signal or the small power signal is amplified at a gain greater than that for the vertical polarization signal or the large power signal in the SOA 215.

The gain controller 522 of the controller 518 then calculates the power difference of the horizontal polarization signal and the vertical polarization signal, dynamically controls the drive current to supply to the SOA 215 so that the power difference becomes smaller than or equal to a predetermined value, and supplies the adjusted drive current to the SOA 215 (step S27).

As described above, the optical signal transmission device 500 according to the fifth embodiment detects the powers of two optical signals contained in the polarization multiplexing signal of after the amplification by the SOA 215, and feedback controls the gain of the SOA 215 using the detected power. The optical signal transmission device 500 thus can accurately reduce the power difference of the horizontal polarization signal and the vertical polarization signal even if the polarization dependent gain property of the SOA 215 is changed due to temperature fluctuation, aging, and the like.

### [f] Sixth Embodiment

An example of controlling the polarization dependent gain of the SOA 215 by supplying the drive current to the SOA 215 has been described in the second embodiment. However, if the gain of the SOA 215 changes, the power of the polarization multiplexing signal output from the optical signal transmission device to the optical transmission path may shift from the target value. In the sixth embodiment, an example of automatically returning the power of the polarization multiplexing signal back to the target value even when the power of the polarization multiplexing signal output to the optical transmission path shifts from the target value will be described.

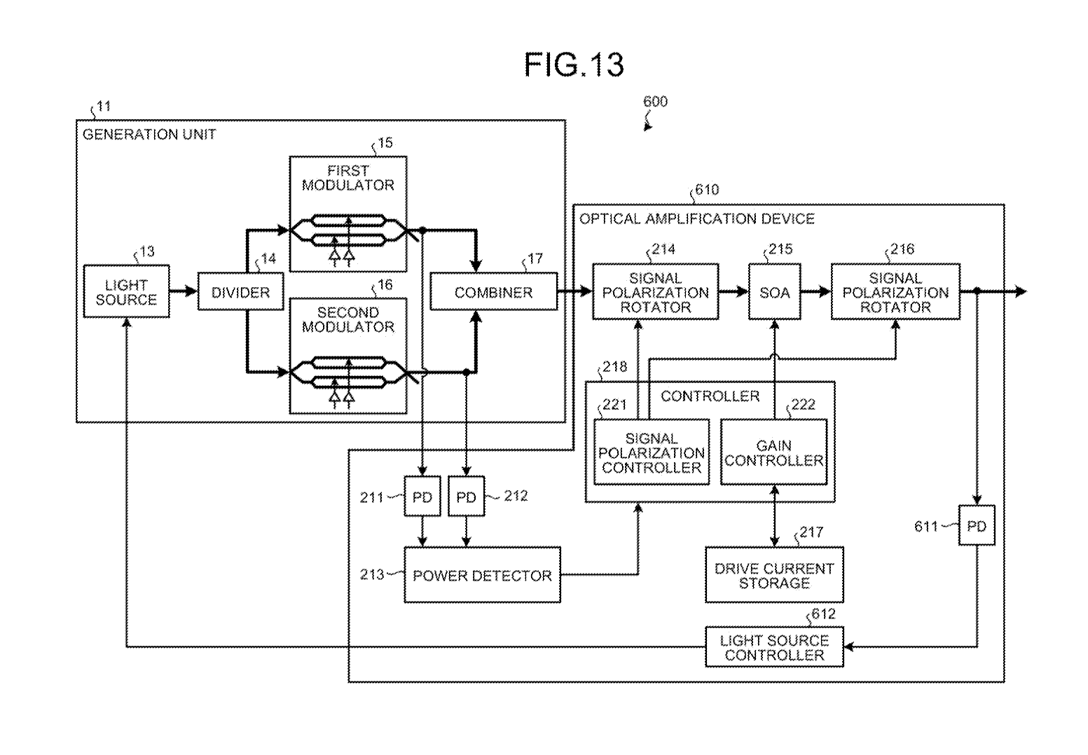

First, the configuration of an optical signal transmission device according to the sixth embodiment will be described. FIG. 13 is a view illustrating a configuration of an optical signal transmission device 600 according to the sixth embodiment. As illustrated in the figure, the optical signal transmission device 600 according to the sixth embodiment includes the generation unit 11 and an optical amplification device 610. The generation unit 11 is similar to the generation unit 11 illustrated in FIG. 31.

The optical amplification device 610 includes the PD 211, the PD 212, the power detector 213, the signal polarization rotator 214, the SOA 215, the signal polarization rotator 216, the drive current storage 217, the controller 218, a PD 611, and a light source controller 612. The PD 211, the PD212, the power detector 213, the signal polarization rotator 214, and the SOA 215 are processing units similar to the PD 211, the PD 212, the power detector 213, the signal polarization rotator 214, and the SOA 215 illustrated in FIG. 5. The signal polarization rotator 216, the drive current storage 217, and the controller 218 are processing units similar to the signal polarization rotator 216, the drive current storage 217, and the controller 218 illustrated in FIG. 5.

The PD 611 converts the polarization multiplexing signal output from the signal polarization rotator 216 on the post-stage of the SOA 215 to the optical transmission path to an electric signal, and outputs the same to the light source controller 612. In other words, the PD 611 converts the polarization multiplexing signal (hereinafter referred to as “amplification signal”) containing the horizontal polarization signal and the vertical polarization signal of after the amplification by the SOA 215 to an electric signal, and outputs the same to the light source controller 612.

The light source controller 612 detects the power of the amplification signal using the electric signal input from the PD 611, and controls the power of a continuous-wave light output from the light source of the generation unit 11 so that the detected power of the amplification signal matches the target value. The total value or the average value of the powers of the horizontal polarization signal and the vertical polarization signal contained in the amplification signal is used for the power of the amplification signal. The light source controller 612 illustrated in FIG. 13 is an integrated circuit such as an ASIC or an FPGA.

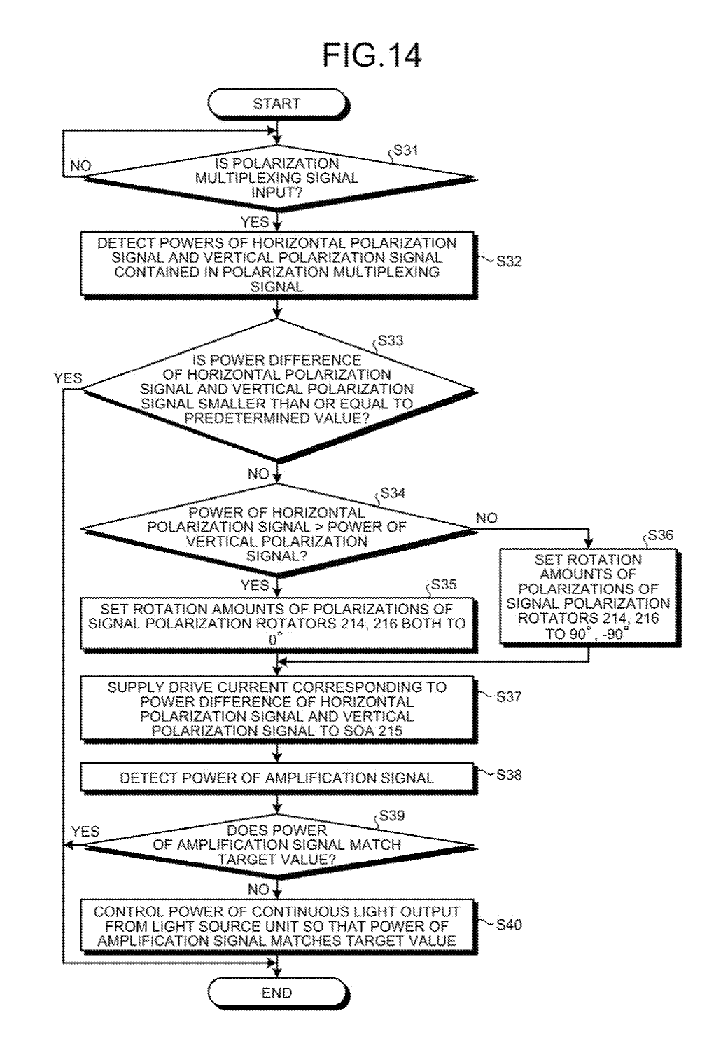

An example of a process in which the optical amplification device 610 of the optical signal transmission device 600 illustrated in FIG. 13 amplifies the polarization multiplexing signal and outputs the same to the optical transmission path will now be described. FIG. 14 is a flowchart illustrating the processing procedure of the optical amplification device 610 according to the sixth embodiment. As illustrated in the figure, the optical amplification device 610 determines whether or not the polarization multiplexing signal is input from the generation unit 11 (step S31), and waits until input (negative in step S31). When the polarization multiplexing signal is input from the generation unit 11 (positive in step S31), the power detector 213 detects the powers of the horizontal polarization signal and the vertical polarization signal contained in the polarization multiplexing signal (step S32). The power detector 213 then outputs the detected powers of the horizontal polarization signal and the vertical polarization signal to the controller 218.

The signal polarization controller 221 of the controller 218 then determines whether or not the power difference of the horizontal polarization signal and the vertical polarization signal is smaller than or equal to a predetermined value (step S33). The predetermined value here is a value as close as possible to zero and for example, is a value smaller than 0.5 dB. If the power difference of the horizontal polarization signal and the vertical polarization signal is smaller than or equal to the predetermined value (positive in step S33), the signal polarization controller 221 terminates the process. If the power difference of the horizontal polarization signal and the vertical polarization signal exceeds a predetermined value (negative in step S33), the signal polarization controller 221 compares the magnitude relationship of the power of the horizontal polarization signal and the power of the vertical polarization signal (step S34).

If the power of the horizontal polarization signal is larger than the power of the vertical polarization signal (positive in step S34), the signal polarization controller 221 sets the rotation amounts of the polarizations of the signal polarization rotators 214, 216 both to 0° (step S35). The polarization of the horizontal polarization signal and the polarization of the vertical polarization signal thus match the horizontal polarization and the vertical polarization in the SOA 215. In the SOA 215, the gain corresponding to the vertical polarization is greater than the gain corresponding to the horizontal polarization. Therefore, the vertical polarization signal or the small power signal is amplified at a gain greater than that for the horizontal polarization signal or the large power signal in the SOA 215.

If the power of the horizontal polarization signal is smaller than the power of the vertical polarization signal (negative in step S34), the signal polarization controller 221 sets the rotation amounts of the polarizations of the signal polarization rotators 214, 216 to 90°, −90°, respectively (step S36). The polarization of the horizontal polarization signal and the polarization of the vertical polarization signal thus match the vertical polarization and the vertical polarization in the SOA 215. In the SOA 215, the gain corresponding to the vertical polarization is greater than the gain corresponding to the horizontal polarization. Therefore, the horizontal polarization signal or the small power signal is amplified at a gain greater than that for the vertical polarization signal or the large power signal in the SOA 215.

The gain controller 222 of the controller 218 then reads out the drive current corresponding to the power difference of the horizontal polarization signal and the vertical polarization signal from the drive current storage 217, and supplies the same to the SOA 215 (step S37).

The light source controller 612 then detects the power of the amplification signal using the electric signal input from the PD 611 (step S38). For instance, the light source controller 612 detects the sum value or the average value of the powers of the horizontal polarization signal and the vertical polarization signal contained in the amplification signal as the power of the amplification signal. The light source controller 612 then determines whether or not the power of the amplification signal matches the target value (step S39), and terminates the process if it matches (positive in step S39). If the power of the amplification signal does not match the target value (negative in step S39), the light source controller 612 controls the power of the continuous-wave light output from the light source 13 of the generation unit 11 so that the power of the amplification signal matches the target value (step S40).

As described above, the optical signal transmission device 600 according to the sixth embodiment controls the power of the continuous-wave light output from the light source 13 and automatically returns the power of the polarization multiplexing signal to the target value when the power of the polarization multiplexing signal output to the optical transmission path after the amplification by the SOA 215 shifts from the target value. Thus, the designers of the optical signal transmission device 600 do not need to reset the target value. Therefore, the optical signal transmission device 600 can alleviate the load on the designers.

### [g] Seventh Embodiment

In the sixth embodiment, an example of controlling the power of the continuous-wave light output from the light source 13 so that the power of the polarization multiplexing signal output to the optical transmission path after the amplification by the SOA 215 matches the target value has been described. However, the polarization multiplexing signal may be attenuated so that the power of the polarization multiplexing signal output to the optical transmission path after the amplification by the SOA 215 matches the target value. In the seventh embodiment, an example of attenuating the polarization multiplexing signal so that the power of the polarization multiplexing signal output to the optical transmission path after the amplification by the SOA 215 matches the target value will be described.

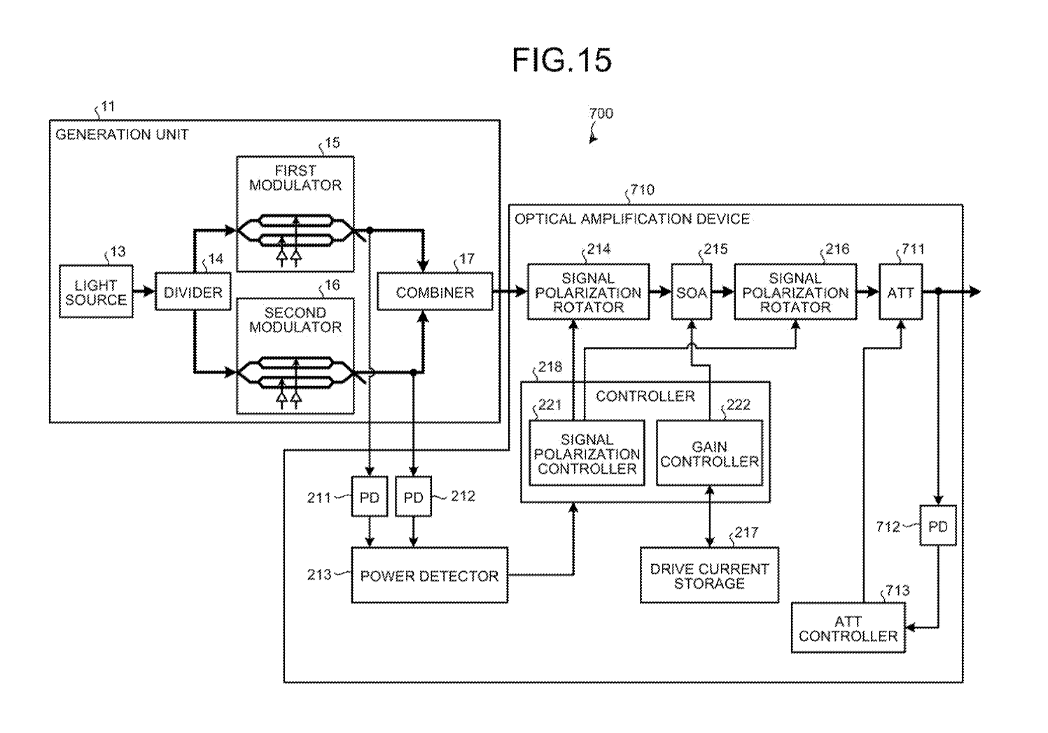

First, the configuration of an optical signal transmission device 700 according to the seventh embodiment will be described. FIG. 15 is a view illustrating a configuration of the optical signal transmission device 700 according to the seventh embodiment. As illustrated in the figure, the optical signal transmission device 700 according to the seventh embodiment includes the generation unit 11 and an optical amplification device 710. The generation unit 11 is similar to the generation unit 11 illustrated in FIG. 31.

The optical amplification device 710 includes the PD 211, the PD 212, the power detector 213, the signal polarization rotator 214, the SOA 215, the signal polarization rotator 216, the drive current storage 217, the controller 218, an Attenuator (ATT) 711, a PD 712, and an ATT controller 713. The PD 211, the PD212, the power detector 213, the signal polarization rotator 214, and the SOA 215 are processing units similar to the PD 211, the PD 212, the power detector 213, the signal polarization rotator 214, and the SOA 215 illustrated in FIG. 5. The signal polarization rotator 216, the drive current storage 217, and the controller 218 are processing units similar to the signal polarization rotator 216, the drive current storage 217, and the controller 218 illustrated in FIG. 5.

The ATT 711 attenuates the power of the polarization multiplexing signal output from the signal polarization rotator 216 on the post-stage of the SOA 215. In other words, the ATT 711 attenuates the power of the polarization multiplexing signal (hereinafter referred to as “amplification signal”) containing the horizontal polarization signal and the vertical polarization signal of after the amplification by the SOA 215. The ATT 711 then outputs the attenuated amplification signal to an optical transmission path (not illustrated). The PD 712 converts the amplification signal output from the ATT 711 to the optical transmission path to an electric signal, and outputs the same to the ATT controller 713.

The ATT controller 713 detects the power of the amplification signal using the electric signal input from the PD 712, and controls the attenuation amount of the ATT 711 so that the detected power of the amplification signal matches the target value. The total value or the average value of the powers of the horizontal polarization signal and the vertical polarization signal contained in the amplification signal is used for the power of the amplification signal. The ATT controller 713 illustrated in FIG. 15 is an integrated circuit such as an ASIC or an FPGA.

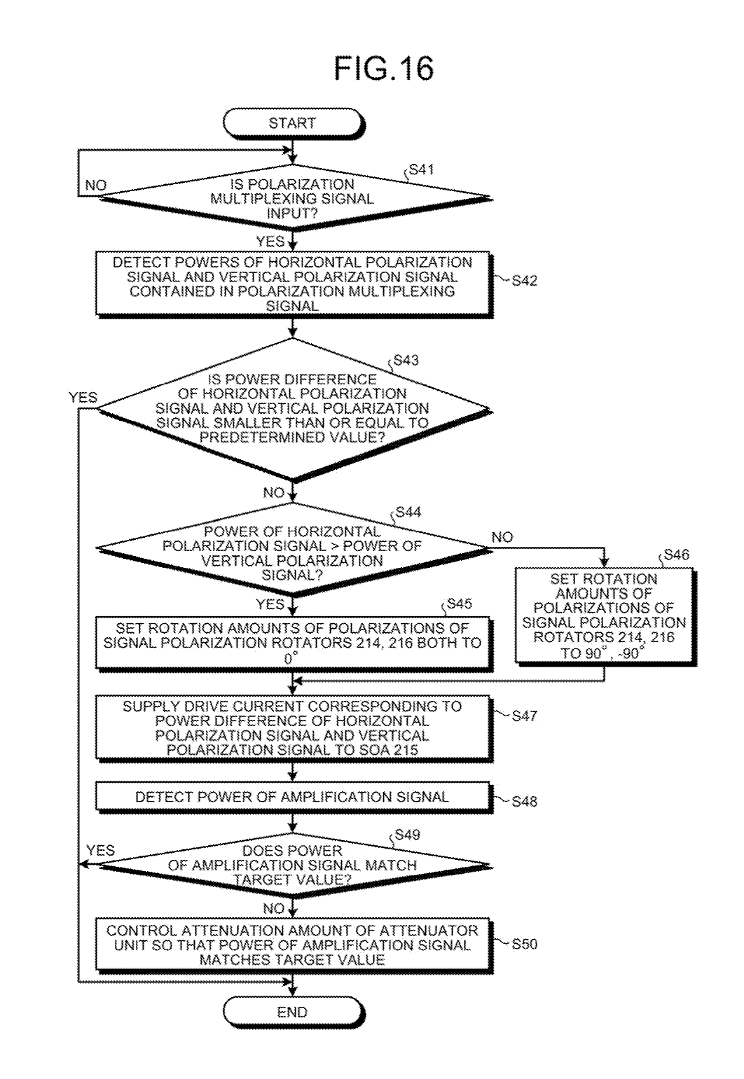

An example of a process in which the optical amplification device 710 of the optical signal transmission device 700 illustrated in FIG. 15 amplifies the polarization multiplexing signal and outputs the same to the optical transmission path will now be described. FIG. 16 is a flowchart illustrating the processing procedure of the optical amplification device 710 according to the seventh embodiment. As illustrated in the figure, the optical amplification device 710 determines whether or not the polarization multiplexing signal is input from the generation unit 11 (step S41), and waits until input (negative in step S41). When the polarization multiplexing signal is input from the generation unit 11 (positive in step S41), the power detector 213 detects the powers of the horizontal polarization signal and the vertical polarization signal contained in the polarization multiplexing signal (step S42). The power detector 213 then outputs the detected powers of the horizontal polarization signal and the vertical polarization signal to the controller 218.

The signal polarization controller 221 of the controller 218 then determines whether or not the power difference of the horizontal polarization signal and the vertical polarization signal is smaller than or equal to a predetermined value (step S43). The predetermined value here is a value as close as possible to zero and for example, is a value smaller than 0.5 dB. If the power difference of the horizontal polarization signal and the vertical polarization signal is smaller than or equal to the predetermined value (positive in step S43), the signal polarization controller 221 terminates the process. If the power difference of the horizontal polarization signal and the vertical polarization signal exceeds a predetermined value (negative in step S43), the signal polarization controller 221 compares the magnitude relationship of the power of the horizontal polarization signal and the power of the vertical polarization signal (step S44).

If the power of the horizontal polarization signal is larger than the power of the vertical polarization signal (positive in step S44), the signal polarization controller 221 sets the rotation amounts of the polarizations of the signal polarization rotators 214, 216 both to 0° (step S45). The polarization of the horizontal polarization signal and the polarization of the vertical polarization signal thus match the horizontal polarization and the vertical polarization in the SOA 215. In the SOA 215, the gain corresponding to the vertical polarization is greater than the gain corresponding to the horizontal polarization. Therefore, the vertical polarization signal or the small power signal is amplified at a gain greater than that for the horizontal polarization signal or the large power signal in the SOA 215.

If the power of the horizontal polarization signal is smaller than the power of the vertical polarization signal (negative in step S44), the signal polarization controller 221 sets the rotation amounts of the polarizations of the signal polarization rotators 214, 216 to 90°, −90°, respectively (step S46). The polarization of the horizontal polarization signal and the polarization of the vertical polarization signal thus match the vertical polarization and the horizontal polarization in the SOA 215. In the SOA 215, the gain corresponding to the vertical polarization is greater than the gain corresponding to the horizontal polarization. Therefore, the horizontal polarization signal or the small power signal is amplified at a gain greater than that for the vertical polarization signal or the large power signal in the SOA 215.

The gain controller 222 of the controller 218 then calculates the power difference of the horizontal polarization signal and the vertical polarization signal, reads out the drive current corresponding to the calculated power difference from the drive current storage 217, and supplies the same to the SOA 215 (step S47).

The ATT controller 713 then detects the power of the amplification signal using the electric signal input from the PD 712 (step S48). For instance, the ATT controller 713 detects the average value of the powers of the horizontal polarization signal and the vertical polarization signal contained in the amplification signal as the power of the amplification signal. The ATT controller 713 then determines whether or not the power of the amplification signal matches the target value (step S49), and terminates the process if it matches (positive in step S49). If the power of the amplification signal does not match the target value (negative in step S49), the ATT controller 713 controls the attenuation amount of the ATT 711 so that the power of the amplification signal matches the target value (step S50).

As described above, the optical signal transmission device 700 according to the seventh embodiment attenuates the polarization multiplexing signal so that the power of the polarization multiplexing signal output to the optical transmission path after the amplification by the SOA 215 matches the target value. Thus, the designers of the optical signal transmission device 700 do not need to reset the target value. Therefore, the optical signal transmission device 700 can alleviate the load on the designers.

### [h] Eighth Embodiment

In the second embodiment, an example of reducing the power difference between the two optical signals contained in the polarization multiplexing signal using one SOA 215. However, the power difference between the two optical signals contained in the polarization multiplexing signal may be reduced using two SOA. In the eighth embodiment, an example of reducing the power difference between two optical signals contained in the polarization multiplexing signal using two SOA will be described.

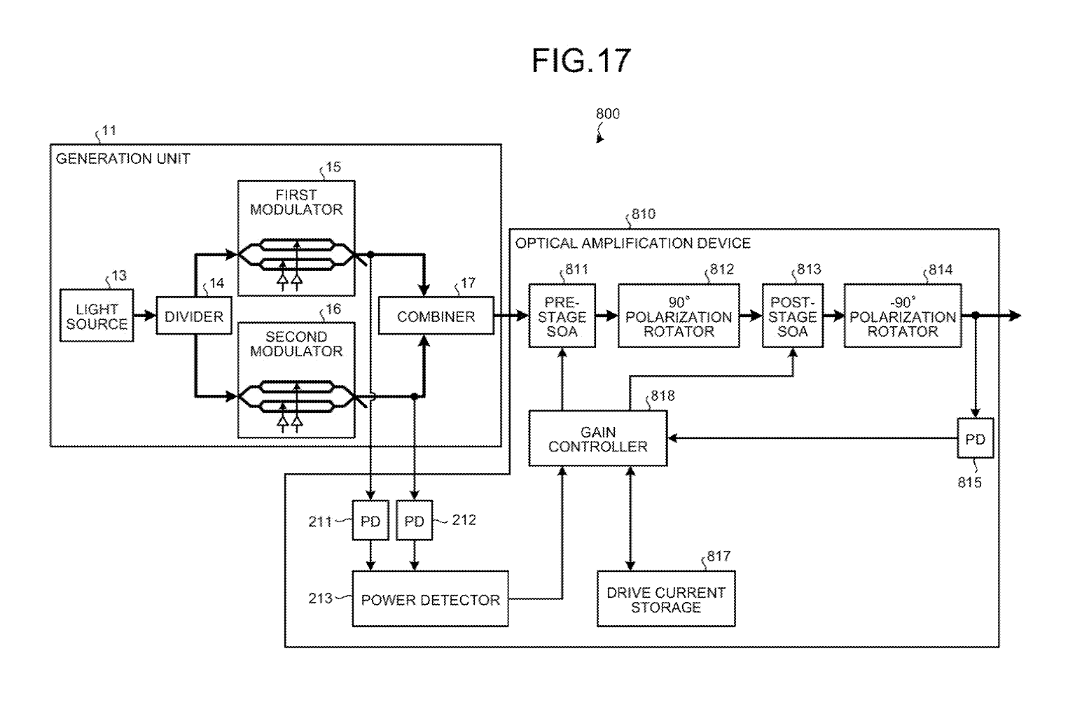

First, the configuration of an optical signal transmission device according to the eighth embodiment will be described. FIG. 17 is a view illustrating a configuration of an optical signal transmission device 800 according to the eighth embodiment. As illustrated in the figure, the optical signal transmission device 800 according to the eighth embodiment includes the generation unit 11 and an optical amplification device 810. The generation unit 11 is similar to the generation unit 11 illustrated in FIG. 31.

The optical amplification device 810 includes the PD 211, the PD 212, the power detector 213, a pre-stage SOA 811, a 90° polarization rotator 812, a post-stage SOA 813, a −90° polarization rotator 814, a PD 815, a drive current storage 817, and a gain controller 818. The PD 211, the PD 212, and the power detector 213 are processing units similar to the PD 211, the PD 212, and the power detector 213 illustrated in FIG. 5.

The pre-stage SOA 811 is a semiconductor optical amplifier having a polarization dependent gain property similar to the SOA 215 illustrated in FIG. 5. In other words, the gain corresponding to the vertical polarization is greater than the gain corresponding to the horizontal polarization in the pre-stage SOA 811. The pre-stage SOA 811 amplifies the vertical polarization signal of the horizontal polarization signal and the vertical polarization signal contained in the polarization multiplexing signal input from the generation unit 11 at the gain greater than that for the horizontal polarization signal, and outputs the amplified polarization multiplexing signal to the 90° polarization rotator 812. The pre-stage SOA 811 changes its gain according to a first drive current supplied from the gain controller 818, to be described later.

The 90° polarization rotator 812 rotates by 90° the polarizations of the horizontal polarization signal and the vertical polarization signal contained in the polarization multiplexing signal input from the pre-stage SOA 811, and reverse rotates the same. Thus, the polarization of the horizontal polarization signal becomes the vertical polarization, and the polarization of the vertical polarization signal becomes the horizontal polarization. In the following description, the horizontal polarization signal that became the vertical polarization by reverse rotation of the polarization by the 90° polarization rotator 812 is called the vertical horizontal polarization signal, and the vertical polarization signal that became the horizontal polarization by reverse rotation of the polarization by the 90° polarization rotator 812 is called the horizontal vertical polarization signal. The 90° polarization rotator 812 outputs the polarization multiplexing signal containing the vertical horizontal polarization signal and the horizontal vertical polarization signal to the post-stage SOA 813.

The post-stage SOA 813 is a semiconductor optical amplifier having a polarization dependent gain property similar to the SOA 215 illustrated in FIG. 5. In other words, the gain corresponding to the vertical polarization is greater than the gain corresponding to the horizontal polarization in the post-stage SOA 813. The post-stage SOA 813 amplifies the vertical horizontal polarization signal of the vertical horizontal polarization signal and the horizontal vertical polarization signal contained in the polarization multiplexing signal input from the 90° polarization rotator 812 at the gain greater than that for the horizontal vertical polarization signal, and outputs the amplified polarization multiplexing signal to the −90° polarization rotator 814. The post-stage SOA 813 changes its gain according to a second drive current supplied from the gain controller 818, to be described later.

The −90° polarization rotator 814 rotates by 90° the polarizations of the vertical horizontal polarization signal and the horizontal vertical polarization signal contained in the polarization multiplexing signal input from the post-stage SOA 813, and reverse rotates the same. The vertical horizontal polarization signal thus returns to the horizontal polarization signal, and the horizontal vertical polarization signal returns to the vertical polarization signal. The −90° polarization rotator 814 outputs the polarization multiplexing signal containing the horizontal polarization signal and the vertical polarization signal to the optical transmission path (not illustrated). The PD 815 converts the polarization multiplexing signal output from the −90° polarization rotator 814 to the optical transmission path to an electric signal, and outputs the same to the gain controller 818.

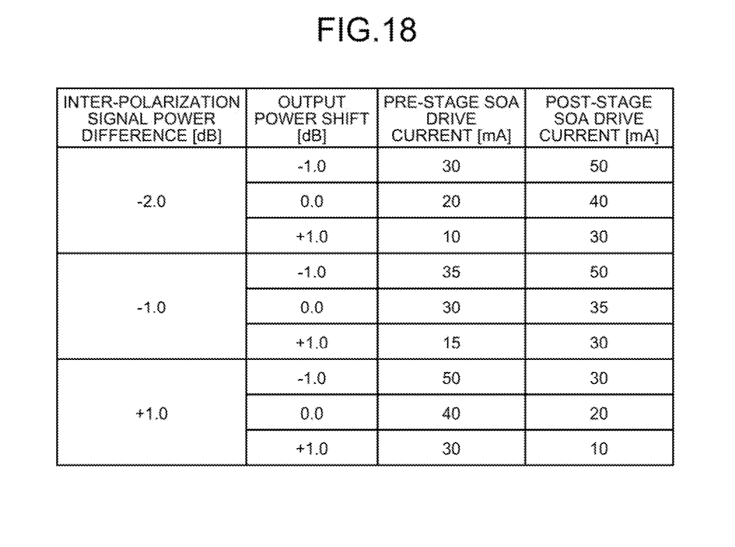

The drive current storage 817 stores the drive current supplied from the gain controller 818 to the pre-stage SOA 811 and the post-stage SOA 813. FIG. 18 is a view illustrating one example of the drive current storage 817. As illustrated in the figure, the drive current storage 817 stores items such as “inter-polarization signal power difference”, “output power shift”, “pre-stage SOA drive current”, and “post-stage SOA drive current” in correspondence to each other. The “inter-polarization signal power difference” indicates the power difference of the horizontal polarization signal and the vertical polarization signal contained in the polarization multiplexing signal, where the negative sign means that the horizontal polarization signal corresponds to the small power signal and the positive sign means that the vertical polarization signal corresponds to the small power signal. The “output power shift” indicates the difference of the power of the polarization multiplexing signal output to the optical transmission path and the target value. The “pre-stage SOA drive current” indicates the drive current of the pre-stage SOA 811 (hereinafter also referred to as “first drive current”). The “post-stage SOA drive current” indicates the drive current of the post-stage SOA 813 (hereinafter also referred to as “second drive current”).

The “pre-stage SOA drive current” and the “post-stage SOA drive current” in the drive current storage 817 are set by the designers using the polarization dependent gain property of the SOA 215 illustrated in FIG. 6. For instance, consider a case in which the power difference of the horizontal polarization signal and the vertical polarization signal is about 2 dB, and the horizontal polarization signal is the small power signal. The “output power shift” is assumed as zero to simplify the description. In this case, the designers set “40 mA”, which is the drive current at which the polarization dependent gain of the SOA 215 becomes 2.5 dB, to the “post-stage SOA drive current” corresponding to the “inter-polarization signal power difference” and the “−2.0 dB” using the polarization dependent gain property of the SOA 215 illustrated in FIG. 6. The designers set “20 mA”, which is the drive current at which the polarization dependent gain of the SOA 215 becomes 0.5 dB, to the “pre-stage SOA drive current” corresponding to the “inter-polarization signal power difference” and the “−2.0 dB”. Thus, the designers set the “post-stage SOA drive current” to a larger value than the “pre-stage SOA drive current when the horizontal polarization signal corresponds to the small power signal. The post-stage SOA 813 then can amplify the vertical horizontal polarization signal of the vertical horizontal polarization signal and the horizontal vertical polarization signal contained in the polarization multiplexing signal input from the 90° polarization rotator 812 at a gain larger than that for the horizontal vertical polarization signal.

Returning back to the description of FIG. 17, the gain controller 818 controls the gain of the pre-stage SOA 811 and the gain of the post-stage SOA 813 based on the powers of the horizontal polarization signal and the vertical polarization signal input from the power detector 213 and the electric signal input from the PD 815. Specifically, when receiving the powers of the horizontal polarization signal and the vertical polarization signal from the power detector 213, the gain controller 818 calculates the power difference of the horizontal polarization signal and the vertical polarization signal. The gain controller 818 also detects the power of the polarization multiplexing signal using the electric signal input from the PD 815. The sum value or the average value of the powers of the horizontal polarization signal and the vertical polarization signal contained in the polarization multiplexing signal is employed for the power of the polarization multiplexing signal. The gain controller 818 calculates the output power shift or the difference of the detected power of the polarization multiplexing signal and the target value.

The gain controller 818 reads out the first and second drive currents corresponding to the power difference and the output power shift of the horizontal polarization signal and the vertical polarization signal from the drive current storage 817. The gain controller 818 then supplies the read first and second drive currents to the pre-stage SOA 811 and the post-stage SOA 813, respectively.

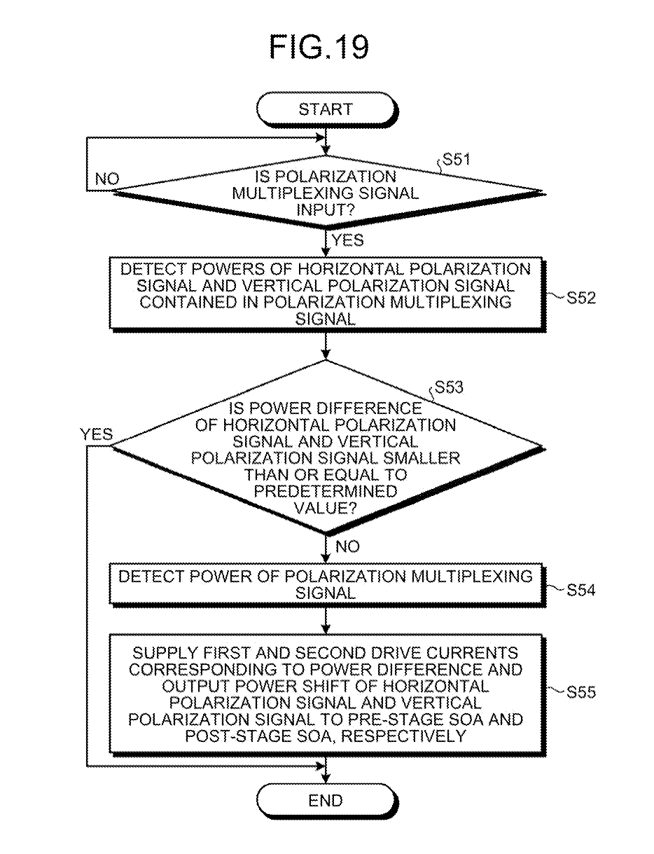

An example of a process in which the optical amplification device 810 arranged in the optical signal transmission device 800 illustrated in FIG. 17 amplifies the polarization multiplexing signal and outputs the same to the optical transmission path will now be described. FIG. 19 is a flowchart illustrating the processing procedure of the optical amplification device 810 according to the eighth embodiment. As illustrated in the figure, the optical amplification device 810 determines whether or not the polarization multiplexing signal is input from the generation unit 11 (step S51), and waits until input (negative in step S51). When the polarization multiplexing signal is input from the generation unit 11 (positive in step S51), the power detector 213 detects the powers of the horizontal polarization signal and the vertical polarization signal contained in the polarization multiplexing signal (step S52). The power detector 213 then outputs the detected powers of the horizontal polarization signal and the vertical polarization signal to the gain controller 818.

The gain controller 818 then determines whether or not the power difference of the horizontal polarization signal and the vertical polarization signal is smaller than or equal to a predetermined value (step S53). The predetermined value here is a value as close as possible to zero and for example, is a value smaller than 0.5 dB. If the power difference of the horizontal polarization signal and the vertical polarization signal is smaller than or equal to the predetermined value (positive in step S53), the gain controller 818 terminates the process.

If the power difference of the horizontal polarization signal and the vertical polarization signal exceeds a predetermined value (negative in step S53), the gain controller 818 detects the power of the polarization multiplexing signal using the electric signal input from the PD 815 (step S54). The sum value or the average value of the powers of the horizontal polarization signal and the vertical polarization signal contained in the polarization multiplexing signal is employed for the power of the polarization multiplexing signal. The gain controller 818 calculates the power difference of the horizontal polarization signal and the vertical polarization signal. The gain controller 818 also calculates the output power shift or the difference of the power of the polarization multiplexing signal and the target value.

The gain controller 818 then reads out the first and second drive currents corresponding to the power difference and the output power shift of the horizontal polarization signal and the vertical polarization signal from the drive current storage 817, and supplies the drive currents to the pre-stage SOA 811 and the post-stage SOA 813, respectively (step S55).

As described above, the optical signal transmission device 800 according to the eighth embodiment reduces the power difference between two optical signals contained in the polarization multiplexing signal using the pre-stage SOA 811 and the post-stage SOA 813. The optical signal transmission device 800 thus can omit the process of rotating the polarization rotator and the processing speed of the entire device becomes higher compared to the example of reducing the power difference between two optical signals contained in the polarization multiplexing signal using one SOA.

### [i] Ninth Embodiment

In the second to eighth embodiments, an example of reducing the power difference between two optical signals contained in the polarization multiplexing signal using the SOA has been described. However, the power difference between two optical signals contained in the polarization multiplexing signal may be reduced using a rare earth doped fiber optical amplifier. In the ninth embodiment, an example of reducing the power difference between two optical signals contained in the polarization multiplexing signal using the rare earth doped fiber optical amplifier will be described.

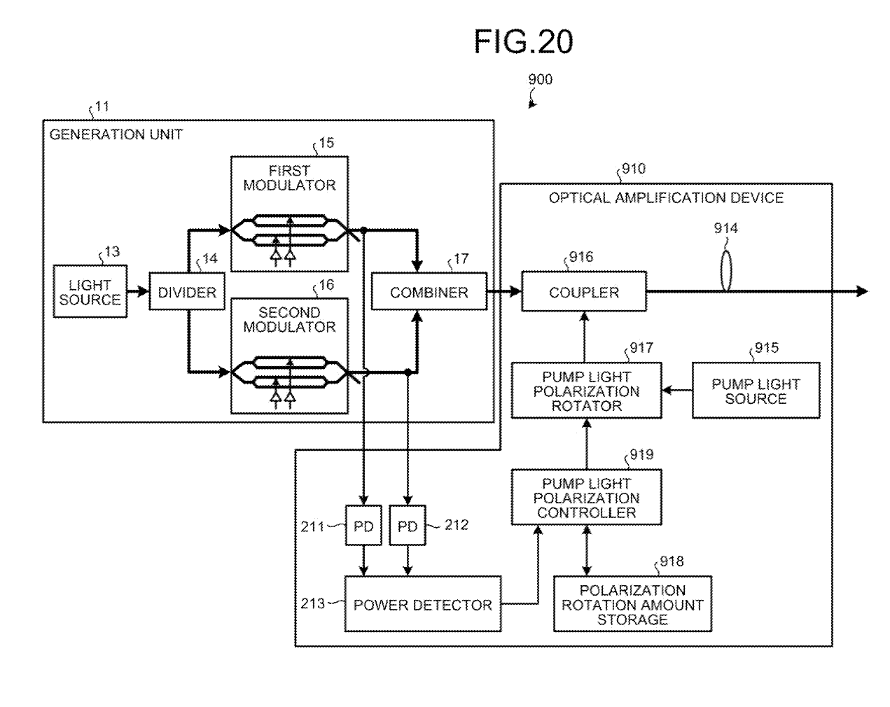

First, the configuration of an optical signal transmission device according to the ninth embodiment will be described. FIG. 20 is a view illustrating a configuration of an optical signal transmission device 900 according to the ninth embodiment. As illustrated in the figure, the optical signal transmission device 900 according to the ninth embodiment includes the generation unit 11 and an optical amplification device 910. The generation unit 11 is similar to the generation unit 11 illustrated in FIG. 31.

The optical amplification device 910 includes the PD 211, the PD 212, the power detector 213, a Erbium Doped Fiber (EDF) 914, a pump light source 915, a coupler 916, a pump light polarization rotator 917, a polarization rotation amount storage 918, and a pump light polarization controller 919. The PD 211, the PD 212, and the power detector 213 are processing units similar to the PD 211, the PD 212, and the power detector 213 illustrated in FIG. 5.

The EDF 914 is a rare earth doped fiber in which erbium ion, which is a rare earth, is added to an optical fiber, which is an amplification medium. The EDF 914 amplifies the horizontal polarization signal and the vertical polarization signal contained in the polarization multiplexing signal input from the generation unit 11, and outputs the same to the optical transmission path (not illustrated). The pump light source 915 outputs a pump light towards the EDF 914. The coupler 916 combines the polarization multiplexing signal input from the generation unit 11 and the pump light input from the pump light source 915, and outputs the same to the EDF 914.

The EDF 914, the pump light source 915, and the coupler 916 are the rare earth doped fiber optical amplifier called the Erbium Doped Fiber Amplifier (EDFA). In the EDFA, the erbium ions in the EDF 914 are pumped by the pump light input from the coupler 916, and the polarization multiplexing signal is input from the coupler 916 with respect to the pumped erbium ions so that induced emission occurs. As a result, the horizontal polarization signal and the vertical polarization signal contained in the polarization multiplexing signal are amplified. A polarization hole burning phenomenon occurs in the EDF 914 when the horizontal polarization signal and the vertical polarization signal contained in the polarization multiplexing signal are amplified. The polarization hole burning phenomenon is a phenomenon where the gain corresponding to the optical signal of the polarization parallel to the polarization of the pump light becomes greater than the gain corresponding to the optical signal of the polarization not parallel to the polarization of the pump light in the EDF 914.

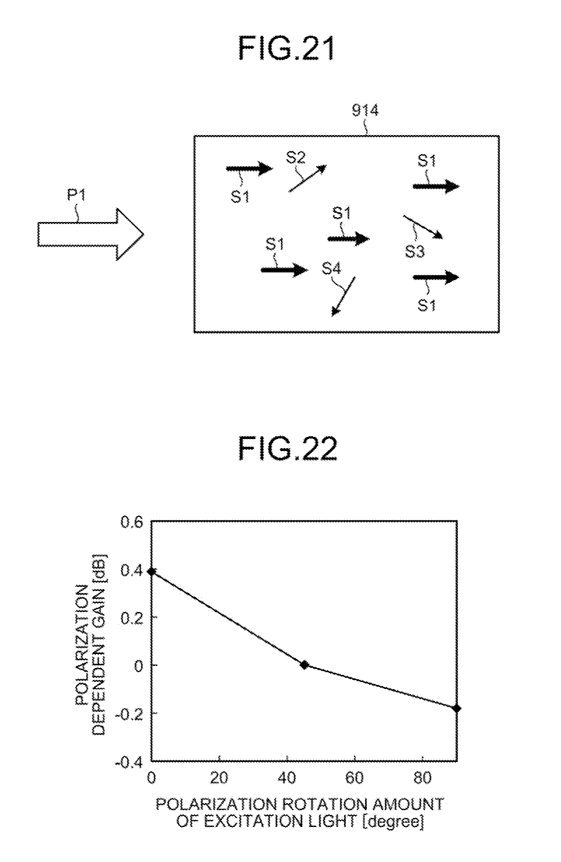

FIG. 21 is a view describing the polarization hole burning phenomenon that occurs in the EDF 914. As illustrated in the figure, the gain corresponding to the optical signal of the polarization S1 parallel to the polarization P1 of the pump light output from the pump light source 915 becomes greater than the gain corresponding to the optical signal of the polarizations S2 to S4 not parallel to the polarization of the pump light in the EDF 914. The optical signal transmission device 900 according to the present example focuses on the polarization hole burning phenomenon, and causes the EDF 914 to generate the polarization dependent gain property by rotating the polarization of the pump light output from the pump light source 915 to the EDF 914.

FIG. 22 is a view describing one example of the polarization dependent gain property generated in the EDF 914. The horizontal axis of FIG. 22 illustrates the rotation amount (degree) of the polarization of the pump light output from the pump light source 915 to the EDF 914, and the vertical axis of FIG. 22 illustrates the polarization dependent gain (dB) or a value obtained by subtracting the gain corresponding to the horizontal polarization from the gain corresponding to the vertical polarization. Assume that the polarization of the pump light is a vertical polarization when the rotation amount of the polarization of the pump light is 0°, and the polarization of the pump light is a horizontal polarization when the rotation amount of the polarization of the pump light is 90°. As illustrated in the figure, the gain corresponding to the vertical polarization becomes greater than the gain corresponding to the horizontal polarization and the polarization dependent gain becomes greater as the rotation amount of the polarization of the pump light output from the pump light source 915 to the EDF 914 approaches 0° in the EDF 914. In the EDF 914, the polarization of the pump light becomes the vertical polarization and the polarization dependent gain becomes a maximum when the rotation amount of the polarization of the pump light output from the pump light source 915 to the EDF 914 is 0°.

In the EDF 914, the gain corresponding to the horizontal polarization becomes greater than the gain corresponding to the vertical polarization and the polarization dependent gain becomes smaller as the rotation amount of the polarization of the pump light output from the pump light source 915 to the EDF 914 approaches 90°. In the EDF 914, the polarization of the pump light becomes the horizontal polarization and the polarization dependent gain becomes a minimum when the rotation amount of the polarization of the excitation light output from the pump light source 915 to the EDF 914 is 90°.

Returning back to FIG. 20, the configuration of the optical amplification device 910 for causing the EDF 914 to generate the polarization dependent gain property by rotating the polarization of the pump light output from the pump light source 915 to the EDF 914 will be described below.

The pump light polarization rotator 917 rotates the polarization of the pump light output from the pump light source 915 to the EDF 914. Specifically, the pump light polarization rotator 917 rotates the polarization of the pump light output from the pump light source 915 to the EDF 914 in the range from 0° to 90° according to the control by the pump light polarization controller 919, to be described later. The pump light polarization rotator 917 then outputs the pump light in which the polarization is rotated to the coupler 916.

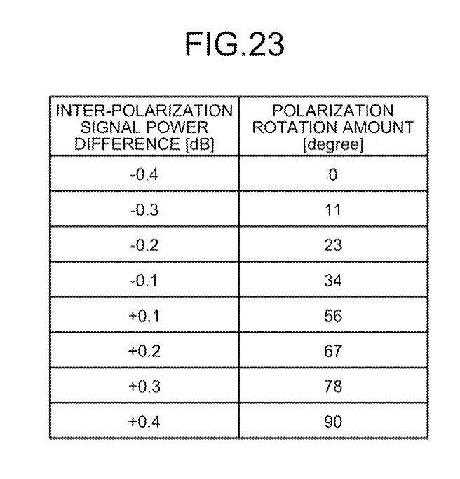

The polarization rotation amount storage 918 stores the rotation amount of the polarization of the pump light output from the pump light source 915 to the EDF 914. FIG. 23 is a view illustrating one example of the polarization rotation amount storage 918. As illustrated in the figure, the polarization rotation amount storage 918 stores items such as “inter-polarization signal power difference” and “polarization rotation amount” in correspondence to each other. The “inter-polarization signal power difference” indicates the power difference between the horizontal polarization signal and the vertical polarization signal contained in the polarization multiplexing signal, where the negative sign means that the vertical polarization signal corresponds to the small power signal and the positive sign means that the horizontal polarization signal corresponds to the small power signal. The “polarization rotation amount” indicates the rotation amount of the polarization of the pump light output from the pump light source 915 to the EDF 914.

The “polarization rotation amount” in the polarization rotation amount storage 918 is set by the designers using the polarization dependent gain property of the EDF 914 illustrated in FIG. 22. For instance, consider a case where the power difference of the horizontal polarization signal and the vertical polarization signal are about 0.3 dB, and the vertical polarization signal is the small power signal. In this case, the designers set “11°” or the rotation amount of the polarization at which the polarization dependent gain of the EDF 914 becomes about 0.3 dB as the “polarization rotation amount” corresponding to the “inter-polarization signal power difference”, “−0.3 dB” using the polarization dependent gain property of the EDF 914 illustrated in FIG. 22. The pump light polarization rotator 917 then can rotate the polarization of the pump light so that the polarization of the pump light output from the pump light source 915 approaches the polarization of the vertical polarization signal or the small power signal rather than the polarization of the horizontal polarization signal or the large power signal. In other words, the pump light polarization rotator 917 can rotate the polarization of the pump light so that an angle formed by the polarization of the pump light and the polarization of the vertical polarization signal or the small power signal is smaller than an angle formed by the polarization of the pump light and the polarization of the horizontal polarization signal or the large power signal. As a result, the EDF 914 can amplify the vertical polarization signal contained in the polarization multiplexing signal at a gain greater than that for the horizontal polarization signal.

Returning back to FIG. 20, the pump light polarization controller 919 controls the pump light polarization rotator 917 based on the powers of the horizontal polarization signal and the vertical polarization signal input from the power detector 213. Specifically, the pump light polarization controller 919 calculates the power difference of the horizontal polarization signal and the vertical polarization signal when receiving the powers of the horizontal polarization signal and the vertical polarization signal from the power detector 213. The pump light polarization controller 919 then reads out the polarization rotation amount corresponding to the calculated power difference from the polarization rotation amount storage 918, and sets the read polarization rotation amount in the pump light polarization rotator 917. In this case, the pump light polarization controller 919 controls the pump light polarization rotator 917 so that the angle formed by the polarization of the pump light and the polarization of the small power signal becomes smaller as the power difference becomes larger.

When the power difference is −0.3 dB and the vertical polarization signal is the small power signal, the pump light polarization controller 919 reads out the polarization rotation amount “11°” from the polarization rotation amount storage 918, and sets the same in the pump light polarization rotator 917. The pump light polarization rotator 917 rotates the polarization of the pump light output from the pump light source 915 up to 11°. The polarization of the pump light output from the pump light source 915 then approaches the polarization of the vertical polarization signal or the small power signal rather than that of the horizontal polarization signal or the large power signal. In other words, the angle formed by the polarization of the pump light and the polarization of the vertical polarization signal or the small power signal becomes smaller than the angle formed by the polarization of the pump light and the polarization of the horizontal polarization signal or the large power signal. Therefore, the EDF 914 amplifies the vertical polarization signal or the small power signal at a gain greater than that for the horizontal polarization signal or the large power signal. As a result, the power difference of the horizontal polarization signal and the vertical polarization signal reduces.

When the power difference is −0.4 dB and the vertical polarization signal is the small power signal, the pump light polarization controller 919 reads out the polarization rotation amount “0” from the polarization rotation amount storage 918, and sets the same in the pump light polarization rotator 917. The pump light polarization rotator 917 rotates the polarization of the pump light output from the pump light source 915 up to 0°. The polarization of the pump light output from the pump light source 915 then becomes parallel to the polarization of the vertical polarization signal or the small power signal. Therefore, the EDF 914 amplifies the vertical polarization signal or the small power signal at a maximum value of the gain. As a result, the power difference of the horizontal polarization signal and the vertical polarization signal reduces.

The EDF 914, the pump light source 915, and the coupler 916 illustrated in FIG. 20 serve as the amplifier 112 illustrated in FIG. 1. The pump light polarization rotator 917 and the pump light polarization controller 919 illustrated in FIG. 20 serve as the controller 113 illustrated in FIG. 1.

The pump light polarization controller 919 illustrated in FIG. 20 is an integrated circuit such as an ASIC or an FPGA. The polarization rotation amount storage 918 illustrated in FIG. 20 is a semiconductor memory element such as a RAM, a ROM, or a flash memory.

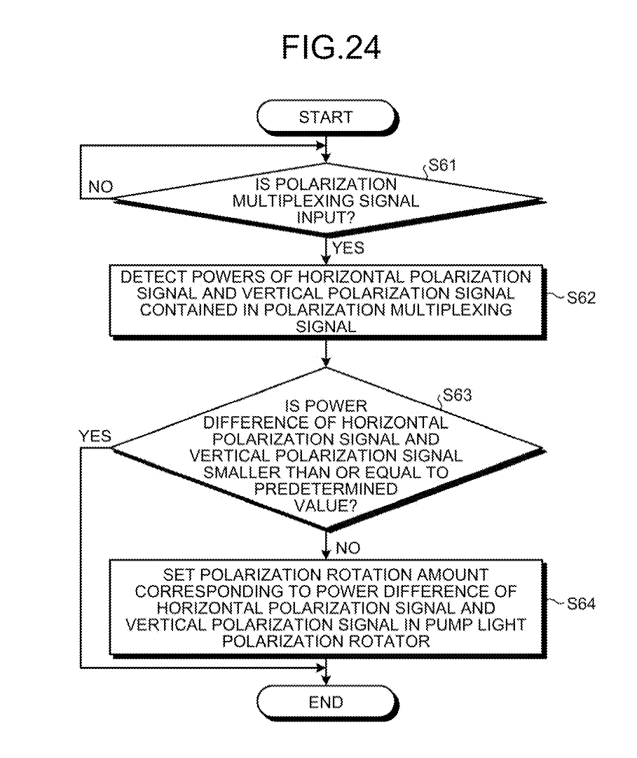

An example of a process in which the optical amplification device 910 arranged in the optical signal transmission device 900 illustrated in FIG. 20 amplifies the polarization multiplexing signal and outputs the same to the optical transmission path will now be described. FIG. 24 is a flowchart illustrating the processing procedure of the optical amplification device 910 according to the ninth embodiment. As illustrated in the figure, the optical amplification device 910 determines whether or not the polarization multiplexing signal is input from the generation unit 11 (step S61), and waits until input (negative in step S61). When the polarization multiplexing signal is input from the generation unit 11 (positive in step S61), the power detector 213 detects the powers of the horizontal polarization signal and the vertical polarization signal contained in the polarization multiplexing signal (step S62). The power detector 213 then outputs the detected powers of the horizontal polarization signal and the vertical polarization signal to the pump light polarization controller 919.

The pump light polarization controller 919 then determines whether or not the power difference of the horizontal polarization signal and the vertical polarization signal is smaller than or equal to a predetermined value (step S63). The predetermined value here is a value as close as possible to zero and for example, is a value smaller than 0.1 dB. If the power difference of the horizontal polarization signal and the vertical polarization signal is smaller than or equal to the predetermined value (positive in step S63), the pump light polarization controller 919 terminates the process. If the power difference of the horizontal polarization signal and the vertical polarization signal exceeds a predetermined value (negative in step S63), the pump light polarization controller 919 reads out the polarization rotation amount corresponding to the power difference of the horizontal polarization signal and the vertical polarization signal from the polarization rotation amount storage 918. The pump light polarization controller 919 then sets the read polarization rotation amount in the pump light polarization rotator 917 (step S64).

As described above, the optical signal transmission device 900 according to the ninth embodiment causes the EDF 914 to generate the polarization dependent gain property by rotating the polarization of the pump light output from the pump light source 915 to the EDF 914. The optical signal transmission device 90° rotates the polarization of the pump light so that the polarization of the pump light output from the pump light source 915 approaches the polarization of the small power signal than the polarization of the large power signal of the horizontal polarization signal and the vertical polarization signal. In other words, the optical signal transmission device 900 amplifies the small power signal of the horizontal polarization signal and the vertical polarization signal at a gain greater than the large power signal. Thus, when power difference is generated between the horizontal polarization signal and the vertical polarization signal contained in the polarization multiplexing signal, the optical signal transmission device 900 can reduce such power difference. As a result, the optical signal transmission device 900 can enhance the transmission characteristics of the polarization multiplexing signal.

The optical signal transmission device 900 according to the ninth embodiment controls the polarization of the pump light such that the polarization of the pump light and the polarization of the small power signal approach as the power difference of the two signals contained in the polarization multiplexing signal becomes greater. The optical signal transmission device 900 thus can have the polarization of the pump light and the polarization of the small power signal parallel to each other, and can amplify the small power signal at a maximum value of the gain of the EDF 914. As a result, the optical signal transmission device 900 can rapidly reduce the power difference of two optical signals contained in the polarization multiplexing signal.

### [j] Tenth Embodiment

In the ninth embodiment, an example of causing the EDF 914 to generate the polarization dependent gain property by rotating the polarization of the pump light has been described. However, if the gain of the EDF 914 changes, the power of the polarization multiplexing signal output from the optical signal transmission device to the optical transmission path may shift from the target value. In the tenth embodiment, an example of automatically returning the power of the polarization multiplexing signal to the target value even when the power of the polarization multiplexing signal output to the optical transmission path is shifted from the target value will be described.

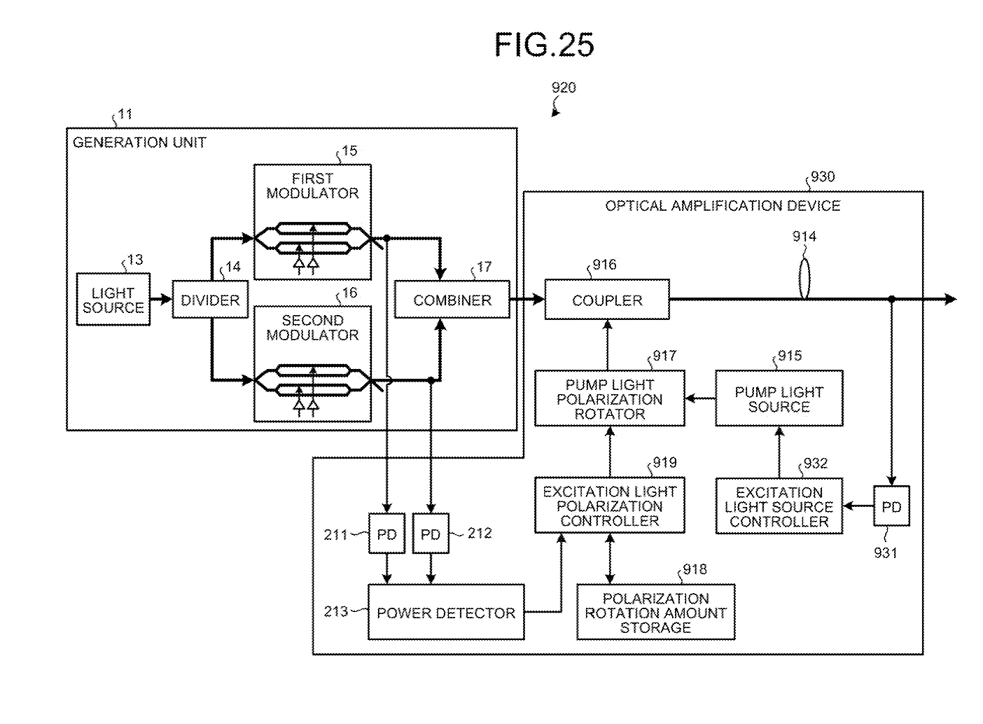

First, the configuration of an optical signal transmission device according to the tenth embodiment will be described. FIG. 25 is a view illustrating a configuration of an optical signal transmission device 920 according to the tenth embodiment. As illustrated in the figure, the optical signal transmission device 920 according to the tenth embodiment includes the generation unit 11 and an optical amplification device 930. The generation unit 11 is similar to the generation unit 11 illustrated in FIG. 31.

The optical amplification device 930 includes the PD 211, the PD 212, the power detector 213, the EDF 914, the pump light source 915, the coupler 916, the pump light polarization rotator 917, the polarization rotation amount storage 918, the pump light polarization controller 919, a PD 931, and a pump light source controller 932. The PD 211, the PD 212, the power detector 213, the EDF 914, and the pump light source 915 are processing units similar to the PD 211, the PD 212, the power detector 213, the EDF 914, and the pump light source 915 illustrated in FIG. 20. The coupler 916, the pump light polarization rotator 917, the polarization rotation amount storage 918, and the pump light polarization controller 919 are processing units similar to the coupler 916, the pump light polarization rotator 917, the polarization rotation amount storage 918, and the pump light polarization controller 919 illustrated in FIG. 20.

The PD 931 converts the polarization multiplexing signal output from the EDF 914 to the optical transmission path to an electric signal and outputs the same to the pump light source controller 932. In other words, the PD 931 converts the polarization multiplexing signal (hereinafter referred to as “amplification signal”) containing the horizontal polarization signal and the vertical polarization signal of after the amplification by the EDF 914 to an electric signal, and outputs the same to the pump light source controller 932.

The pump light source controller 932 detects the power of the amplification signal using the electric signal input from the PD 931, and controls the power of the pump light output from the pump light source 915 so that the detected power of the amplification signal matches the target value. The total average value of the powers of the horizontal polarization signal and the vertical polarization signal contained in the amplification signal is employed for the power of the amplification signal. The power of the amplification signal is not limited to an average value, and may be a larger value or a smaller value of the powers of the horizontal polarization signal and the vertical polarization signal contained in the amplification signal. The pump light source controller 932 illustrated in FIG. 25 is an integrated circuit such as an ASIC or an FPGA.

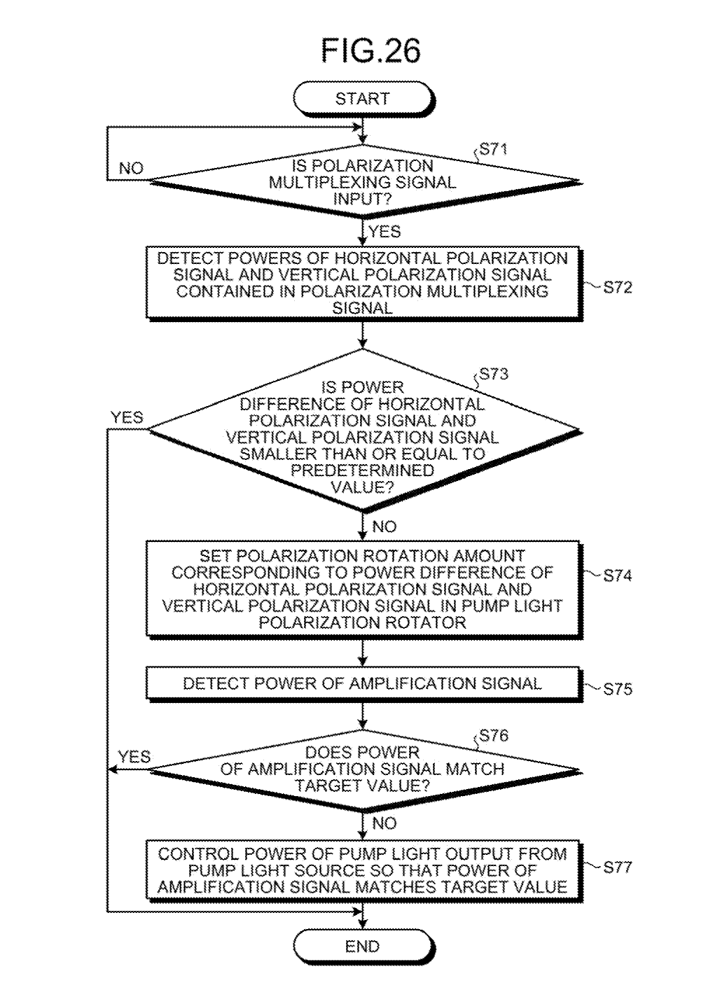

An example of a process in which the optical amplification device 930 of the optical signal transmission device 920 illustrated in FIG. 25 amplifies the polarization multiplexing signal and outputs the same to the optical transmission path will now be described. FIG. 26 is a flowchart illustrating the processing procedure of the optical amplification device 930 according to the tenth embodiment. As illustrated in the figure, the optical amplification device 930 determines whether or not the polarization multiplexing signal is input from the generation unit 11 (step S71), and waits until input (negative in step S71). When the polarization multiplexing signal is input from the generation unit 11 (positive in step S71), the power detector 213 detects the powers of the horizontal polarization signal and the vertical polarization signal contained in the polarization multiplexing signal (step S72). The power detector 213 then outputs the detected powers of the horizontal polarization signal and the vertical polarization signal to the pump light polarization controller 919.

The pump light polarization controller 919 then determines whether or not the power difference of the horizontal polarization signal and the vertical polarization signal is smaller than or equal to a predetermined value (step S73). The predetermined value here is a value as close as possible to zero and for example, is a value smaller than 0.1 dB. If the power difference of the horizontal polarization signal and the vertical polarization signal is smaller than or equal to the predetermined value (positive in step S73), the pump light polarization controller 919 terminates the process. If the power difference of the horizontal polarization signal and the vertical polarization signal exceeds a predetermined value (negative in step S73), the pump light polarization controller 919 reads out the polarization rotation amount corresponding to the power difference of the horizontal polarization signal and the vertical polarization signal from the polarization rotation amount storage 918. The pump light polarization controller 919 then sets the read polarization rotation amount in the pump light polarization rotator 917 (step S74).

The pump light source controller 932 then detects the power of the amplification signal using the electric signal input from the PD 931 (step S75). For instance, the pump light source controller 932 detects the average value of the powers of the horizontal polarization signal and the vertical polarization signal contained in the amplification signal as the power of the amplification signal. The pump light source controller 932 then determines whether or not the power of the amplification signal matches the target value (step S76), and terminates the process if it matches (positive in step S76). If the power of the amplification signal does not match the target value (negative in step S76), the pump light source controller 932 controls the power of the pump light output from the pump light source 915 so that the power of the amplification signal matches the target value (step S77).

As described above, when the power of the polarization multiplexing signal output to the optical transmission path after the amplification by the EDF 914 is shifted from the target value, the optical signal transmission device 920 according to the tenth embodiment automatically returns the power of the polarization multiplexing signal to the target value by controlling the power of the pump light output from the pump light source 915. The designers of the optical signal transmission device 920 thus do not need to reset the target value. Therefore, the optical signal transmission device 920 can alleviate the load on the designers.

### [k] Eleventh Embodiment

In the ninth embodiment, an example of rotating the polarization of the pump light so that the polarization of the pump light output from the pump light source 915 towards the EDF 914 and the polarization of the small power signal contained in the polarization multiplexing signal approach has been described. However, two pump lights having the polarizations that respectively match the polarizations of the two optical signals contained in the polarization multiplexing signal may be output towards the EDF 914, and the powers of the two pump lights may be controlled according to the power difference of the two optical signals. In the eleventh embodiment, an example of outputting two pump lights having the polarizations that respectively match the polarizations of the two optical signals contained in the polarization multiplexing signal towards the EDF 914, and controlling the powers of the two pump lights according to the power difference of the two optical signals will be described.

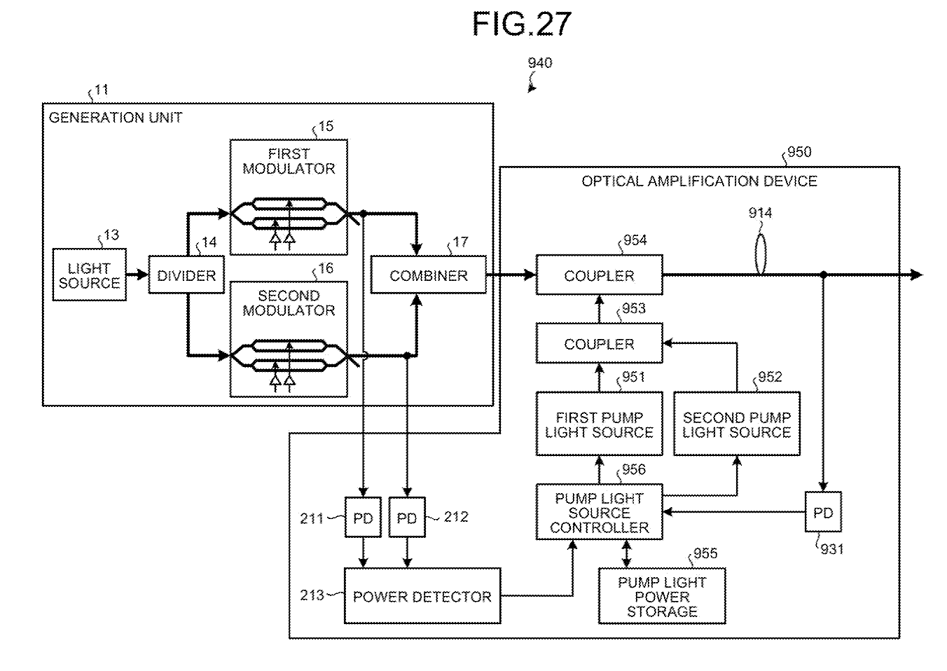

First, the configuration of an optical signal transmission device according to the eleventh embodiment will be described. FIG. 27 is a view illustrating a configuration of an optical signal transmission device 940 according to the eleventh embodiment. As illustrated in the figure, the optical signal transmission device 940 according to the tenth embodiment includes the generation unit 11 and an optical amplification device 950. The generation unit 11 is similar to the generation unit 11 illustrated in FIG. 31.

The optical amplification device 950 includes the PD 211, the PD 212, the power detector 213, the EDF 914, the PD 931, a first pump light source 951, a second pump light source 952, a coupler 953, a coupler 954, an pump light power storage 955, and a pump light source controller 956. The PD 211, the PD 212, the power detector 213, and the EDF 914 are processing units similar to the PD 211, the PD 212, the power detector 213, and the EDF 914 illustrated in FIG. 20. The PD 931 is similar to the PD 931 illustrated in FIG. 25.

The first pump light source 951 outputs the horizontal polarization pump light, which is the excitation light of horizontal polarization that matches the polarization of the horizontal polarization signal of the two optical signals contained in the polarization multiplexing signal, towards the EDF 914. Specifically, the first pump light source 951 outputs the horizontal polarization pump light towards the EDF 914 in accordance with the control of the pump light source controller 956, to be described later.

The second pump light source 952 outputs the vertical polarization pump light, which is the pump light of vertical polarization that matches the polarization of the vertical polarization signal of the two optical signals contained in the polarization multiplexing signal, towards the EDF 914. Specifically, the second pump light source 952 outputs the vertical polarization pump light towards the EDF 914 in accordance with the control of the pump light source controller 956.

The coupler 953 combines the horizontal polarization pump light output from the first pump light source 951 and the vertical polarization excitation pump output from the second pump light source 952 with the respective polarizations orthogonal to each other, and outputs to the coupler 954. The coupler 954 combines the polarization multiplexing signal input from the generation unit 11, and the horizontal polarization pump light and the vertical polarization pump light input from the coupler 953, and outputs to the EDF 914.

The polarization dependent gain property generated in the EDF 914 in the present example will now be described. In the EDF 914, the horizontal polarization signal is mainly amplified by the horizontal polarization pump light since the polarization of the horizontal polarization signal contained in the polarization multiplexing signal and the polarization of the horizontal polarization pump light match. The vertical polarization signal is mainly amplified by the vertical polarization pump light since the polarization of the vertical polarization signal contained in the polarization multiplexing signal and the polarization of the vertical polarization pump light match.

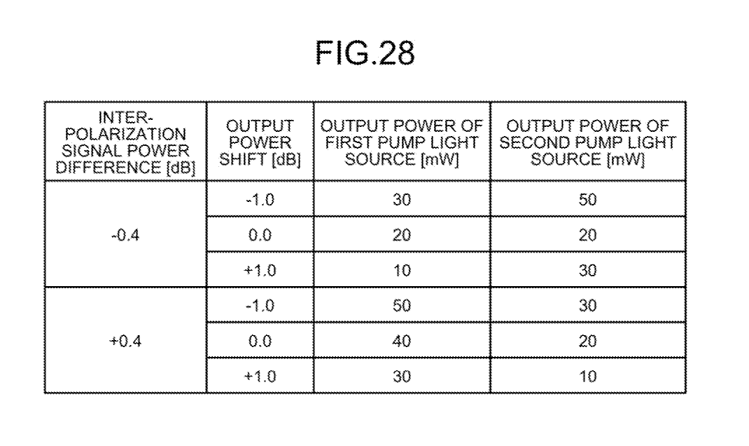

Returning back to the description of FIG. 27, the pump light power storage 955 stores the output power set in the first pump light source 951 and the second pump light source 952 by the pump light source controller 956. FIG. 28 is a view illustrating one example of the pump light power storage 955. As illustrated in the figure, the pump light power storage 955 stores items such as “inter-polarization signal power difference”, “output power shift”, “output power of first pump light source”, and “output power of second pump light source” in correspondence to each other. The “inter-signal power difference” indicates the power difference of the horizontal polarization signal and the vertical polarization signal contained in the polarization multiplexing signal, where the negative sign means that the vertical polarization signal corresponds to the small power signal and the positive sign means that the horizontal polarization signal corresponds to the small power signal. The “output power shift” indicates the difference of the power of the polarization multiplexing signal output to the optical transmission path and the target value. The “output power of the first pump light source” is also referred to as the power (hereinafter referred to as “first output power”) of the horizontal polarization pump light output from the first pump light source 951. The “output power of the second pump light source” is also referred to as the power (hereinafter referred to as “second output power”) of the vertical polarization pump light output from the second pump light source 952.

The magnitude relationship of the “output power of the first pump light source” and the “output power of the second pump light source” in the pump light power storage 955 is set by the designers according to the power difference of the horizontal polarization signal and the vertical polarization signal. Specifically, the designers set the “output power of the second pump light source” to a larger value than the “output power of the first pump light source” when the vertical polarization signal corresponds to the small power signal. The second pump light source 952 then can output the vertical polarization pump light having a larger power than the horizontal polarization pump light of the first pump light source 951 towards the EDF 914, and the vertical polarization signal is mainly amplified by the vertical polarization pump light in the EDF 914. The designers set the “output power of the first pump light source” to a larger value than the “output power of the second pump light source” when the horizontal polarization signal corresponds to the small power signal. The first pump light source 951 then can output the horizontal polarization pump light having a larger power than the vertical polarization pump light of the second pump light source 952 towards the EDF 914, and the horizontal polarization signal is mainly amplified by the horizontal polarization pump light in the EDF 914.

The pump light source controller 956 controls the first pump light source 951 and the second pump light source 952 based on the powers of the horizontal polarization signal and the vertical polarization signal input from the power detector 213, and the electric signal input from the PD 931. Specifically, the pump light source controller 956 calculates the power difference of the horizontal polarization signal and the vertical polarization signal when receiving the powers of the horizontal polarization signal and the vertical polarization signal from the power detector 213. The pump light source controller 956 detects the power of the polarization multiplexing signal using the electric signal input from the PD 931. The average value of the powers of the horizontal polarization signal and the vertical polarization signal contained in the polarization multiplexing signal is used for the power of the polarization multiplexing signal. The power of the polarization multiplexing signal is not limited to the average value, and may be the larger value or the smaller value of the horizontal polarization signal and the vertical polarization signal contained in the polarization multiplexing signal. The pump light source controller 956 then calculates the output power shift or the difference of the detected power of the polarization multiplexing signal and the target value.

The pump light source controller 956 reads out the first and second output powers corresponding to the power difference of the horizontal polarization signal and the vertical polarization signal and the output power shift from the pump light power storage 955. The pump light source controller 956 sets the read first and second output powers in the first pump light source 951 and the second pump light source 952, respectively. For instance, if the vertical polarization signal corresponds to the small power signal, the second pump light source 952 outputs the vertical polarization pump light having larger power than the horizontal polarization pump light of the first pump light source 951 towards the EDF 914. As a result, the vertical polarization signal is mainly amplified by the vertical polarization pump light in the EDF 914. For instance, if the horizontal polarization signal corresponds to the small power signal, the first pump light source 951 outputs the horizontal polarization pump light having larger power than the vertical polarization pump light of the second pump light source 952 towards the EDF 914. As a result, the horizontal polarization signal is mainly amplified by the horizontal polarization pump light in the EDF 914.

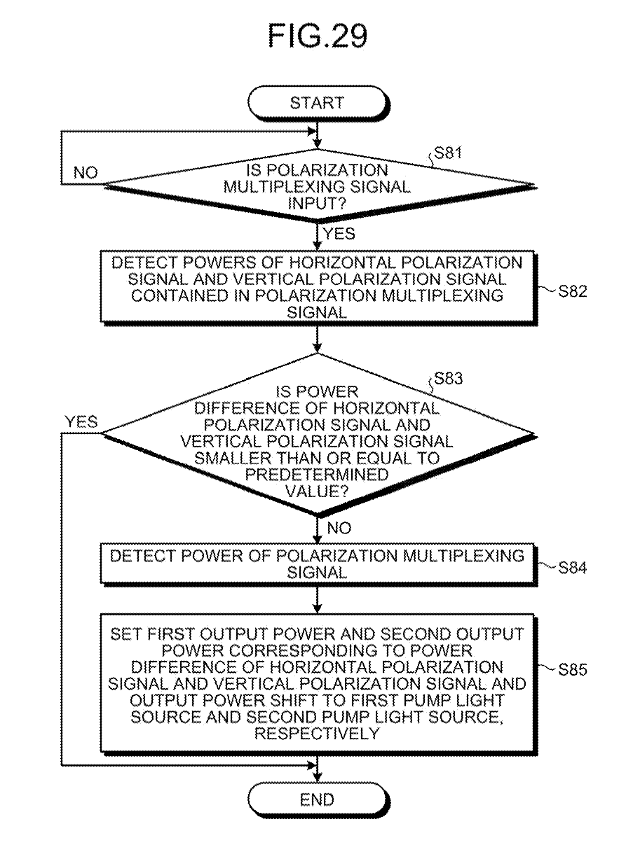

An example of a process in which the optical amplification device 950 of the optical signal transmission device 940 illustrated in FIG. 27 amplifies the polarization multiplexing signal and outputs the same to the optical transmission path will now be described. FIG. 29 is a flowchart illustrating the processing procedure of the optical amplification device according to the eleventh embodiment. As illustrated in the figure, the optical amplification device 950 determines whether or not the polarization multiplexing signal is input from the generation unit 11 (step S81), and waits until input (negative in step S81). When the polarization multiplexing signal is input from the generation unit 11 (positive in step S81), the power detector 213 detects the powers of the horizontal polarization signal and the vertical polarization signal contained in the polarization multiplexing signal (step S82). The power detector 213 then outputs the detected powers of the horizontal polarization signal and the vertical polarization signal to the pump light source controller 956.

The pump light source controller 956 then determines whether or not the power difference of the horizontal polarization signal and the vertical polarization signal is smaller than or equal to a predetermined value (step S83). The predetermined value here is a value as close as possible to zero and for example, is a value smaller than 0.1. If the power difference of the horizontal polarization signal and the vertical polarization signal is smaller than or equal to the predetermined value (positive in step S83), the pump light source controller 956 terminates the process.

If the power difference of the horizontal polarization signal and the vertical polarization signal exceeds a predetermined value (negative in step S83), the pump light source controller 956 detects the power of the polarization multiplexing signal using the electric signal input from the PD 931 (step S84). The average value of the powers of the horizontal polarization signal and the vertical polarization signal contained in the polarization multiplexing signal is used for the power of the polarization multiplexing signal. The pump light source controller 956 then calculates the power difference of the horizontal polarization signal and the vertical polarization signal. The pump light source controller 956 calculates the output power shift or the difference of the power of the polarization multiplexing signal and the target value.

The pump light source controller 956 reads out the first and second output powers corresponding to the power difference of the horizontal polarization signal and the vertical polarization signal and the output power shift from the pump light power storage 955. The pump light source controller 956 supplies the read first and second output powers to the first pump light source 951 and the second pump light source 952, respectively (step S85).

As described above, the optical signal transmission device 940 according to the eleventh embodiment outputs two pump lights having the polarizations that respectively match the polarizations of the two optical signals contained in the polarization multiplexing signal towards the EDF 914, and controls the powers of the two pump lights according to the power difference of the two optical signals. Thus, the optical signal transmission device 940 can reduce the power difference between the two optical signals without performing the process of rotating the polarization of the pump light, and hence the processing load can be alleviated.

### [l] Twelfth Embodiment

The optical signal transmission device described in the second to eleventh embodiments may be implemented in various different modes other than those of the second to eleventh embodiments. In the twelfth embodiment, other examples included in the above-described optical signal transmission device will be described.

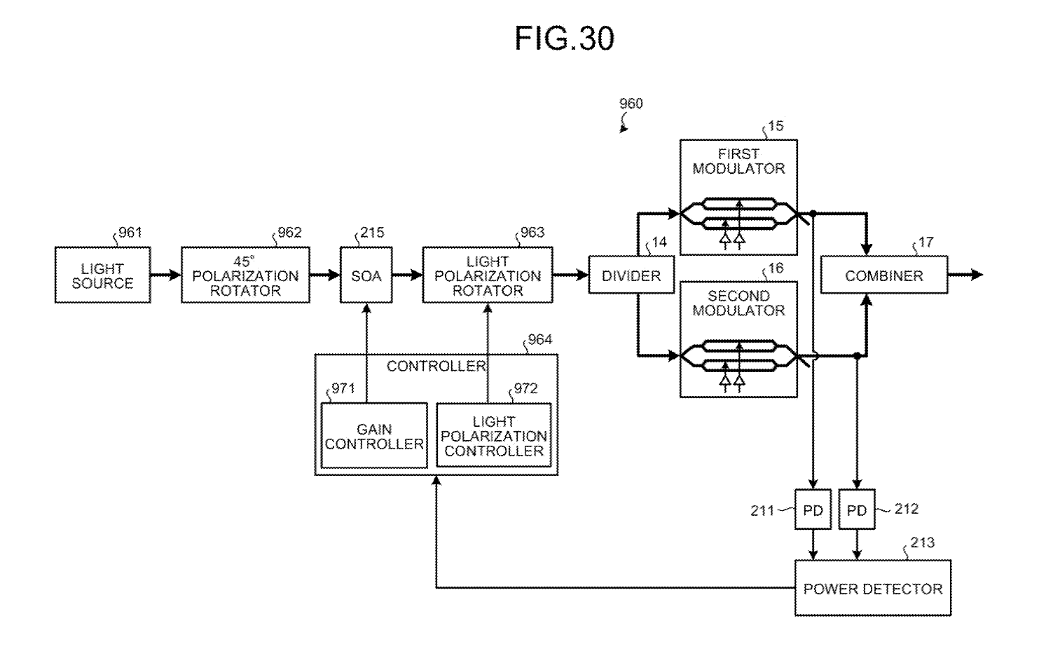

First, other configuration examples related to the optical signal transmission device illustrated in second to eight examples will be described. FIG. 30 is a view illustrating another configuration example of the optical signal transmission device illustrated in the second to eighth embodiments. As illustrated in the figure, an optical signal transmission device 960 includes a light source 961, a 45° polarization rotator 962, the SOA 215, a light polarization rotator 963, the divider 14, the first modulator 15, the second modulator 16, and the combiner 17. The optical signal transmission device 960 also includes the PD 211, the PD 212, the power detector 213, and a controller 964. The SOA 215, the divider 14, the first modulator 15, the second modulator 16, and the combiner 17 are processing units similar to the SOA 215, the divider 14, the first modulator 15, the second modulator 16, and the combiner 17 illustrated in FIG. 15. The PD 211, the PD 212, and the power detector 213 are processing units similar to the PD 211, the PD 212, and the power detector 213 illustrated in FIG. 5.

The light source 961 outputs a continuous-wave light of horizontal polarization or vertical polarization. The 45° polarization rotator 962 rotates the polarization of the continuous-wave light output from the light source 961 by 45° and outputs to the SOA 215. The SOA 215 amplifies, according to polarization rotated by 45° of the continuous-wave light, the power of the continuous-wave light. The light polarization rotator 963 rotates the polarization of the continuous-wave light input from the SOA 215 to the divider 14 if necessary. The divider 14 separates the input continuous-wave light to the horizontal polarization and the vertical polarization.

The controller 964 includes a gain controller 971 and a light polarization controller 972. The gain controller 971 feedback controls the gain of the SOA 215 so that the power difference of the horizontal polarization signal and the vertical polarization signal reduces using the powers of the horizontal polarization signal and the vertical polarization signal input from the power detector 213.

The light polarization controller 972 controls the light polarization rotator 963 so that the power difference of the horizontal polarization signal and the vertical polarization signal reduces. Specifically, the light polarization controller 972 sets the rotation amount of the polarization of the light polarization rotator 963 to 0° when the vertical polarization signal corresponds to the small power signal. The light polarization controller 972 sets the rotation amount of the polarization of the light polarization rotator 963 to 90° when the horizontal polarization signal corresponds to the small power signal.

Thus, the optical signal transmission device 960 can reduce the power difference of the two optical signals contained in the polarization multiplexing signal by amplifying the power of the continuous-wave light output from the light source 961 in the SOA 215.

In the second to eighth embodiments, description has been made using the SOA having the property in which the gain corresponding to the vertical polarization is greater than the gain corresponding to the horizontal polarization for the polarization dependent gain property, but the polarization dependent gain property is not limited thereto. The SOA having the property in which the gain corresponding to the horizontal polarization is greater than the gain corresponding to the vertical polarization for the polarization dependent gain property may be used.

In the ninth and tenth embodiments, the method of rotating the polarization of the pump light so that the polarization of the pump light output from the pump light source 915 towards the EDF 914 and the polarization of the small power signal contained in the polarization multiplexing signal approach has been described. However, the disclosed technique is not limited thereto. For instance, the polarization of the small power signal may be rotated so that the polarization of the pump light and the polarization of the small power signal contained in the polarization multiplexing signal approach, or both the polarization of the pump light and the polarization of the small power signal may be rotated.

The following will be further disclosed in relation to the embodiments including each example described above.

According to the optical signal transmission device disclosed herein, an effect in that the transmission characteristics of the polarization multiplexing signal enhance is obtained.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A optical signal transmission device comprising:
a generation unit that generates a polarization multiplexing signal in which two optical signals, each polarization of which is orthogonal to each other, are combined;
a detector that detects powers of the two optical signals contained in the polarization multiplexing signal generated by the generation unit;
an amplifier that amplifies, according to each polarization of the two optical signals contained in the polarization multiplexing signal generated by the generation unit, the powers of the two optical signals; and
an controller that controls a gain of the amplifier with respect to each polarization of the two optical signals so as to reduce difference in the powers of the two optical signals detected by the detector.

2. The optical signal transmission device according to claim 1, wherein
the amplifier is a semiconductor optical amplifier in which a gain corresponding to a first polarization is greater than a gain corresponding to a second polarization;
the controller includes a signal polarization rotator that rotates the polarizations of the two optical signals and a signal polarization controller that controls the signal polarization rotator so that the polarization of the optical signal with smaller power of the two optical signals matches the first polarization in the semiconductor optical amplifier and the polarization of the optical signal with larger power of the two optical signals matches the second polarization in the semiconductor optical amplifier.

3. The optical signal transmission device according to claim 2, wherein the controller further includes a gain controller that controls a difference of the gain corresponding to the first polarization and the gain corresponding to the second polarization in the semiconductor optical amplifier by supplying a drive current, which increases as the difference in the powers of the two optical signals detected by the detector becomes greater, to the semiconductor amplifier.

4. The optical signal transmission device according to claim 1, wherein
the amplifier is first and second semiconductor optical amplifiers in which a gain corresponding to a first polarization is greater than a gain corresponding to a second polarization; and
the controller includes a 90° polarization rotator, arranged between the first semiconductor optical amplifier and the second semiconductor optical amplifier, that reversely rotates the polarizations of the two light signals output from the first semiconductor optical amplifier to the second semiconductor optical amplifier, and a gain controller that controls the gain of the first semiconductor optical amplifier and the gain of the second semiconductor optical amplifier by supplying a first drive current and a second drive current, which are defined according to the difference in the powers of the two optical signals detected by the detector, to the first semiconductor optical amplifier and the second semiconductor optical amplifier, respectively.

5. The optical signal transmission device according to claim 1, wherein
the amplifier is a rare earth doped fiber optical amplifier including a rare earth doped fiber that amplifies the two optical signals and a pump light source that outputs a pump light towards the rare earth doped fiber; and
the controller includes a pump light polarization rotator that rotates the polarization of the pump light output from the pump light source to the rare earth doped fiber, and an pump light polarization controller that controls the pump light polarization rotator so that an angle formed by the polarization of the pump light and the polarization of the optical signal with smaller power of the two optical signals becomes smaller than an angle formed by the polarization of the pump light and the polarization of the optical signal with larger power of the two optical signals.

6. The optical signal transmission device according to claim 5, wherein the pump light polarization controller controls the pump light polarization rotator so that the angle formed by the polarization of the pump light and the polarization of the optical signal with smaller power becomes smaller as the difference in powers of the two optical signals detected by the detector becomes greater.

7. The optical signal transmission device according to claim 5, further comprising a pump light source controller that detects the power of the polarization multiplexing signal containing the two optical signals amplified by the amplifier, and controls the power of the pump light output from the pump light source so that the detected power of the polarization multiplexing signal matches a target value.

8. The optical signal transmission device according to claim 1, wherein
the amplifier is a rare earth doped fiber optical fiber including a rare earth doped fiber that amplifies the two optical signals, a first pump light source that outputs a first pump light, whose polarization matches the polarization of one optical signal of the two optical signals, towards the rare earth doped fiber, and a second pump light source that outputs a second pump light, whose polarization matches the polarization of the other optical signal of the two optical signals, towards the rare earth doped fiber; and
the controller includes a pump light source controller that controls the power of the first pump light output from the first pump light source and the power of the second pump light output from the second pump light source by setting a first power and a second power, which are defined according to the difference in the powers of the two optical signals detected by the detector, to the first pump light source and the second pump light source, respectively.

9. The optical signal transmission device according to claim 1, wherein the detector detects the powers of the two optical signals using phase conjugate lights of the two optical signals contained in the polarization multiplexing signal generated by the generation unit.

10. The optical signal transmission device according to claim 1, wherein
the generation unit includes a light source that outputs a continuous-wave light, and generates the polarization multiplexing signal by combining the two optical signals generated from the continuous-wave light output from the light source; and
further comprising a light source controller that detects the power of the polarization multiplexing signal containing the two optical signals amplified by the amplifier, and controls the power of the continuous-wave light output from the light source so that the detected power of the polarization multiplexing signal matches a target value.

11. The optical signal transmission device according to claim 1, further comprising an attenuator that attenuates the power of the polarization multiplexing signal containing the two optical signals amplified by the amplifier, and an attenuator controller that detects the power of the polarization multiplexing signal containing the two optical signals amplified by the amplifier, and controls the attenuation amount of the attenuator so that the detected power of the polarization multiplexing signal matches a target value.

12. An optical signal transmission device comprising:
a light source that outputs a continuous-wave light of horizontal polarization or vertical polarization;
a 45° polarization rotator that rotates the polarization of the continuous-wave light output by the light source by 45°;
an amplifier that amplifies, according to the polarization of the continuous-wave light rotated by the 45° polarization rotator, the power of the continuous-wave light;
a generation unit that divides the continuous-wave light amplified by the amplifier into two lights, each polarization of which is orthogonal to each other, and generates a polarization multiplexing signal in which the two optical signals generated based on the two branched lights are combined;
a detector that detects powers of the two optical signals contained in the polarization multiplexing signal generated by the generation unit;
a light polarization rotator that rotates the polarization of the continuous-wave light input from the amplifier to the generation unit; and
a light polarization controller that controls the light polarization rotator so as to reduce difference in the powers of the two optical signals detected by the detector.

13. An optical amplification device comprising,
a detector that detects powers of two lights contained in a polarization multiplexing light in which two lights, each polarization of which is orthogonal to each other, are combined;
an amplifier that amplifies, according to each polarization of the two optical signals, the powers of the two lights contained in the polarization multiplexing light; and
an controller that controls a gain of the amplifier with respect to each polarization of the two optical signals so as to reduce difference in the powers of the two optical signals detected by the detector.

14. An optical amplification device comprising,
a detector that detects powers of two lights contained in a polarization multiplexing light in which two lights, each polarization of which is orthogonal to each other, are combined;
an attenuator that attenuates, according to each polarization of the two optical signals contained in the polarization multiplexing light, the powers of the two lights; and
an controller that controls a loss of the attenuator with respect to each polarization of the two optical signals so as to reduce difference in the powers of the two optical signals detected by the detector.

15. An optical signal transmission method performed by an optical signal transmission device comprising:
a generation unit that generates a polarization multiplexing signal in which two optical signals, each polarization of which is orthogonal to each other, are combined; and
an amplifier that amplifies, according to each polarization of the two optical signals contained in the polarization multiplexing signal generated by the generation unit, the powers of the two optical signals;
the optical signal transmission method comprising:
detecting the powers of the two optical signals contained in the polarization multiplexing signal, and
adjusting a gain of the amplifier with respect to each polarization of the two optical signals so as to reduce difference in the powers of the two optical signals detected by the detecting.
